(19) United States
(12) Patent Application Publication
(10) Pub. No.: US 2022/0022381 A1
(43) Pub. Date: Jan. 27, 2022

(54) LIGHTING DEVICE FOR HORTICULTURE

(71) Applicants: Ying LI, Westmont, IL (US); Satish AGRAWAL, Sudbury, MA (US); Michael G. HORNER, West Roxbury, MA (US); Andrew TURK, Woodbridge, IL (US); Nathaniel KABAT, Burr Ridge, IL (US)

(72) Inventors: Ying LI, Westmont, IL (US); Satish AGRAWAL, Sudbury, MA (US); Michael G. HORNER, West Roxbury, MA (US); Andrew TURK, Woodbridge, IL (US); Nathaniel KABAT, Burr Ridge, IL (US)

(21) Appl. No.: 17/292,420

(22) PCT Filed: Nov. 10, 2019
(86) PCT No.: PCT/US19/60665

§ 371 Date: May 7, 2021

Related U.S. Application Data
(60) Provisional application No. 62/758,444, filed on Nov. 9, 2018.
(60) Provisional application No. 62/850,353, filed on May 20, 2019.
(60) Provisional application No. 62/850,487, filed on May 20, 2019.
(60) Provisional application No. 62/850,350, filed on May 20, 2019.
(60) Provisional application No. 62/850,346, filed on May 20, 2019.
(60) Provisional application No. 62/850,480, filed on May 20, 2019.
(60) Provisional application No. 62/850,483, filed on May 20, 2019.
(60) Provisional application No. 62/850,360, filed on May 20, 2019.
(60) Provisional application No. 62/850,341, filed on May 20, 2019.
(60) Provisional application No. 62/850,477, filed on May 20, 2019.
(60) Provisional application No. 62/851,332, filed on May 22, 2019.

(51) Int. Cl. A01G 7/04; H05B 47/11; F21V 9/02; H01L 27/146

(52) U.S. Cl. CPC A01G 7/045; H05B 47/11; F21Y 2115/10; H01L 27/14643; F21V 9/02

(57) ABSTRACT

A grow light for providing light to one or more plants in a grow area, includes a first light source and a second light source. A first energy conversion component is disposed over the first light source and a second energy conversion component is disposed over the second light source. A power supply is configured to provide power to the first and the second light sources. A controller is configured to control the power supply to provide power to either the first light source or the second light source at a given time. The first energy conversion component converts light received from the first light source into a light having first spectrum and the second energy conversion component converts light received from the second light source into a light having second spectrum different from the first spectrum.

### CROSS REFERENCE TO RELATED APPLICATIONS

The present application claims the benefit of priority under 35 U.S.C. § 119(e) to U.S. Provisional Application Nos. 62/758,444, filed on Nov. 9, 2018, and 62/850,341, 62/850,477, 62/850,480, 62/850,483, 62/850,346, 62/850,350, 62/850,360, 62/850,487, 62/850,353, and 62/851,332, filed on May 20, 2019, all which are incorporated by reference herein by their entireties.

### TECHNICAL FIELD

The present disclosure relates to devices and systems which are configured to provide lighting for horticulture.

### BACKGROUND

Artificial light sources, referred to as grow lights, to stimulate plant growth are used in horticulture where there is insufficient or no naturally occurring light, or where it is desirable to maintain the amount of light available to the plants under controlled conditions (e.g., temperature, CO2 levels, humidity, etc.). Environments where grow lights are used include, for example, grow boxes, grow rooms, greenhouses, indoor gardens, laboratories, vertical farms, or other environments used for plant cultivation. Some examples of grow lights include, but are not limited to, high intensity discharge (HID) lights (e.g., mercury vapor, metal halide, high pressure sodium and conversion bulbs), fluorescent lights (e.g., tube-style fluorescent lights and compact fluorescent lights), and light-emitting diodes (LEDs).

Grow lights typically use point source lighting which produce non-uniform light fields, resulting in uneven plant yield, e.g., lower plant yield away from the center of the light field where intensity of light is the highest. One potential solution is to increase the number of light sources over a defined grow area to increase the uniformity of intensity. This solution, however, comes at increased cost and may not be energy efficient. Grow lights having uniform intensity over a larger grow area are, therefore, desired.

Moreover, Photosynthetically Active Radiation (PAR) is important to evaluate plants' photosynthesis process where each molecule is activated by the absorption of one photon in the primary photochemical process. Most commercial grow lights list their Photosynthetic Photon Flux Density (PPFD) in micromole per sq. meter per sec (μmol/m²-s). PPFD measures the areal density of photons in the 400-700 nm wavelength range. The grow area of the light and the distance from the light fixture are typically specified along with the PPFD. Because, luminous flux (in lumens) is weighted according to a model (a “luminosity function”) of the sensitivity of the human eye to various wavelengths, it is not relevant to plants. Thus, grow lights need to provide photosynthetically active radiation with appropriate spectrum and spectral distribution which may depend on various growth stages of the plant as well as particular plant species.

### BRIEF DESCRIPTION OF DRAWINGS

The following detailed description, will be better understood when read in conjunction with the appended drawings. For the purpose of illustrating the disclosure, there are shown in the drawings embodiments which are presently preferred. It should be understood, however, that the disclosure can be embodied in different forms and thus should not be construed as being limited to the embodiments set forth herein.

FIG. 1 illustrates a lighting arrangement which may be used for cultivating plants, in accordance with an embodiment of the present disclosure.

FIGS. 2A and 2B illustrate an example lighting system according to an embodiment of the present disclosure.

FIG. 3A illustrates an example of an edge-lit lighting source that can be used as a grow light, in accordance with an embodiment of the present disclosure.

FIG. 3B illustrates a side-channel disposed inside the frame of an edge-lit luminaire, in accordance with an embodiment of the present disclosure.

FIGS. 4A-4C each illustrate an example of a lighting device (or grow light), in accordance with an embodiment of the present disclosure.

FIGS. 4D and 4E illustrate examples of lighting devices with different shapes, in accordance with some embodiments of the present disclosure.

FIG. 5A illustrates an embodiment of a lighting device including a mechanism for changing the energy conversion component, in accordance with an embodiment of the present disclosure.

FIG. 5B illustrates an alternate embodiment of a lighting device including a mechanism for changing the energy conversion component, in accordance with an embodiment of the present disclosure.

FIG. 6 illustrates an example of a back-lit lighting source that can be used as a grow light, in accordance with an embodiment of the present disclosure.

FIG. 7A illustrates an example of a lighting device (or grow light), in accordance with an embodiment of the present disclosure.

FIG. 7B illustrates an example of a back-lit lighting device having four types of energy conversion films, in accordance with an embodiment of the present disclosure.

FIGS. 7C-7F show various examples of positioning of LED strips within the lighting device, in accordance with an embodiment of the present disclosure.

FIGS. 8A-8D illustrate example spectra achievable using different energy conversion films, in accordance with an embodiment of the present disclosure.

FIGS. 9A-9D illustrate example spectra having different blue to red peak intensity ratios achievable using different energy conversion films, in accordance with an embodiment of the present disclosure.

FIG.10 illustrates a conceptual representation of the grow light control system, in accordance with an embodiment of the present disclosure.

FIG. 11 shows a circuit diagram for an excitation light source, in accordance with an embodiment of the present disclosure.

FIG. 12 illustrates a schematic diagram of horticulture lighting system including a growth control sensor having a photodetector, an excitation source, a wavelength selection element, in accordance with an embodiment of the present disclosure.

FIG. 13 illustrates a cross-sectional view of an example mechanical embodiment of the photo-diode portion of the growth control sensor, in accordance with an embodiment of the present disclosure.

FIG. 14 illustrates a schematic diagram of horticulture lighting system including a growth control sensor and a communication module, in accordance with an embodiment of the present disclosure.

FIG. 15 illustrates a block diagram of interaction between various modules of a horticulture lighting system, in accordance with an embodiment of the present disclosure.

FIGS. 16A and 16B illustrate an alternate apparatus for converting an existing light source into a light source capable of providing light with high red/yellow content or light with high blue content, in accordance with an embodiment of the present disclosure.

FIG. 17 shows an example lighting arrangement utilizing a horticulture lighting system, in accordance with an embodiment of the present disclosure.

FIG. 18 shows a graph illustrating plant stage determination based on sensor readings, in accordance with an embodiment of the present disclosure.

FIG. 19 shows a graph showing change in sensor readings and corresponding change in power of the grow light adjusted based on the sensor readings over time, in accordance with an embodiment of the present disclosure.

### DETAILED DESCRIPTION

The present disclosure provides lighting systems that, in some embodiments, are able to overcome deficiencies of typical grow lights. In some embodiments, a lighting system according to the present disclosure is configured to produce more uniform lighting across the entire grow area.

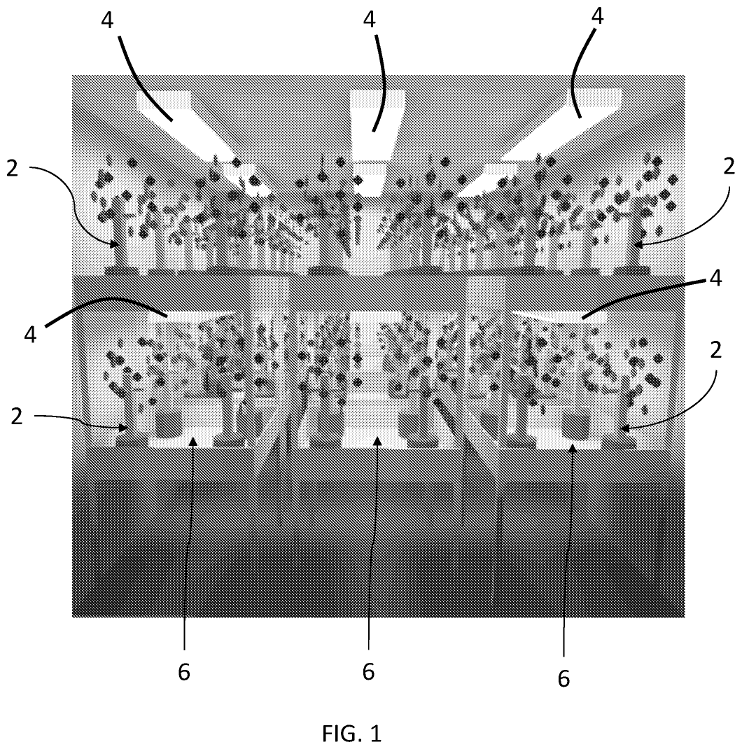

Referring now to the drawings in detail, wherein like reference numerals indicate like elements throughout, there is shown in FIG. 1 a lighting arrangement which may be used for cultivating plants according to certain embodiments of the present disclosure. In particular, FIG. 1 illustrates one or more grow lights 4 which are each positioned and configured to provide light to a grow area 6 containing one or more plants 2. Plants 2 may be situated in grow area 6 in separate containers (e.g., pots), or a plurality of plants 2 may be planted together in grow area 6 (e.g., in a plant bed). Grow area 6 may be located, for example, on a raised table, rack, tray, or other support structure configured to hold and/or support plants 2. Furthermore, in some embodiments, two or more grow areas 6 may be arranged in rows and/or stacked vertically one on top of another.

The illustrated arrangement as shown in FIG. 1 can be configured for use in grow boxes, grow rooms, greenhouses, indoor gardens, laboratories, vertical farms, or other environments typically used for plant cultivation. In some embodiments, plants 2 may include, for example, any type of crop plant or ornamental plant that may be cultivated (e.g., vegetables, fruits, herbs, grains, medicinal plants, fiber plants, flowers, trees, shrubs, etc.). Furthermore, the term “plant” as used herein is not necessarily limited to organisms in the kingdom Plantae, but rather may refer to photosynthetic organisms in general, including seaweeds, algae, and photosynthetic prokaryotes (e.g., cyanobacteria).

In some embodiments, grow lights 4 may be positioned vertically above plants 2 and be configured as overhead lighting to provide light downward onto plants 2. In some embodiments, each grow area 6 may be provided with a single grow light 4 arranged and configured to provide a sufficient amount of light to cover the grow area 6. In other embodiments, each grow area 6 may be provided with a plurality of grow lights 4 arranged and configured to provide a sufficient amount of light to cover the grow area 6. In some embodiments, each grow light 4 includes one or more light emitting diode (LED) lighting panels, for example, an LED lighting panel which has a configuration as described in U.S. Patent Application Publication No. 2018/0203180, which is incorporated herein by reference in its entirety. In some embodiments, a grow light 4 includes a light guide panel which is configured to provide relatively uniform lighting over a grow area. In some embodiments, grow light 4 includes a light guide panel and one or more strips of LEDs positioned at or proximate an edge of the light guide panel configured to emit photons into the edge of the light guide panel. In some such embodiments, the light guide panel is configured to direct photons emitted by the LEDs into the edge of the light guide panel to another surface of the light guide panel (e.g., a bottom surface) where the photons are extracted from the light guide panel and directed to the grow area 6. In further embodiments, grow light 4 may include one or more energy conversion films configured to convert the wavelength of the light emitted by the LEDs to a different wavelength before it reaches plants 2. In some embodiments, grow light 4 is configured such that the energy conversion film may be removed and replaced with a different energy conversion film.

In some embodiments, a grow light 4 may be in fixed position relative to a grow area 6. In other embodiments, a grow light 4 may be movable relative to a grow area 6. For example, grow light 4 may be positioned on a movable support (e.g., a platform or frame) which is configured to move grow light 4 closer or away from grow area 6. In some embodiments, grow area 6 may additionally or alternatively be positioned on a movable support configured to move plants 2 closer or away from grow light 4. Thus, in some embodiments, the distance between a grow light 4 and plants 2 may be varied, for example, to control the intensity of light reaching plants 2, wherein moving grow light 4 closer to plants 2 increases the intensity of light reaching plants 2 and vice versa. This may be desirable, in some embodiments, where different growth stages of plants 2 may have different lighting intensity requirements for optimal yield.

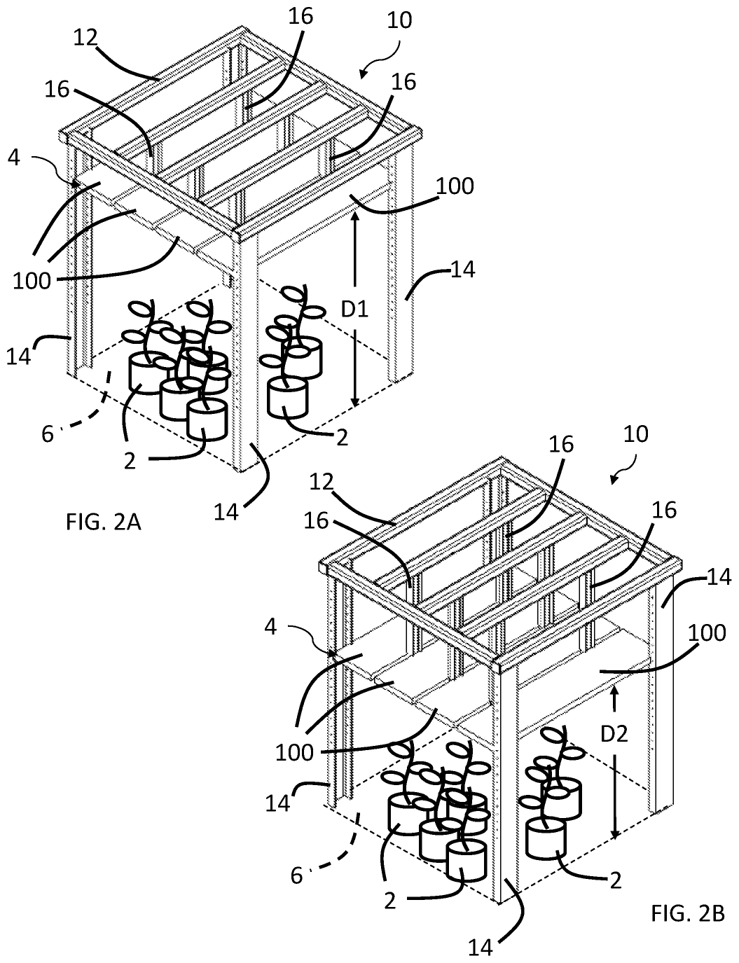

FIGS. 2A and 2B illustrate an example lighting system 10 according to an embodiment of the present disclosure, which is configured to allow grow light 4 to move closer or away from grow area 6 and plants 2 positioned within grow area 6. In some embodiments, grow light 4 includes four or more separate light panels 100. In some embodiments, grow light 4 has dimensions that is equal to or substantially equal to dimensions of grow area 6 (e.g., 4 feet by 4 feet). In some embodiments, grow area 6 has dimensions which are greater than dimensions of grow light 4. In other embodiments, grow area 6 has dimensions which are smaller than dimensions of grow light 4. In some embodiments, grow light 4 is not point source lighting (e.g., exposed light bulbs). In some embodiments, grow light 4 includes one or more light panels 100 which are mounted to a support 12. In some embodiments, the one or more light panels 100 are positioned between support 12 and grow area 6. In some embodiments, each light panel 100 may be configured as a thin, rectangular panel as shown, which may have dimensions, for example, of about 1-foot-wide by 4-feet-long by 0.25-inch-thick. In some embodiments, for example, light panel 100 may be thicker than 0.25 inches, for example, 0.5 inches to 1 inch. Other shapes and dimensions for light panels 100 may be used in other embodiments. In some embodiments, grow light 4 includes two or more separate light panels 100 that can be arranged in a generally coplanar manner. In some embodiments, grow light 4 includes three or more separate light panels 100.

In some embodiments, support 12 includes a frame or rack that is supported by one or more legs 14 which hold support 12 above grow area 6 in which plants 2 may be positioned. In some embodiments, the one or more legs 14 extend from the frame to grow area 6 where plants 2 may be positioned. Support 12 and/or legs 14 may be constructed from metal, metal alloy, or other sufficiently sturdy materials to support grow light 4. In some embodiments, grow light 4 is movably coupled to support 12 such that grow light 4 is capable of moving in at least one degree of freedom with respect to support 12. In some embodiments, grow light 4 is configured to move in one or at least one linear direction (e.g., vertically) with respect to support 12. In some embodiments, grow light 4 is configured to move with respect to support 12 such that a distance between grow light 4 and grow area 6 may be varied. For example, as shown in FIG. 2A, grow light 4 is in a first, raised position that is spaced a distance D1 from grow area 6. In, FIG. 2B, grow light 4 is in a second, lowered position that is spaced a distance D2 from grow area 6 where D1 is greater than D2. Grow light 4 may be movable to any distance between D1 and D2 in some embodiments. D1 may be, for example, about 6 feet while D2 may be about 4 feet. It should be appreciated that these values of D1 and D2 are for illustration only, and that lighting system 10 could be configured such that grow light 4 may be positioned at other distances.

In some embodiments, grow light 4 is connected to support 12 by one or more struts 16. In some such embodiments, one or more struts 16 may have adjustable lengths in order to allow grow light 4 to move with respect to support 12 and grow area 6. For example, in some embodiments, one or more struts 16 may have a telescoping construction allowing for struts 16 to extend or contract. In some embodiments, the one or more struts 16 include linear actuators, for example, mechanical, hydraulic, pneumatic, electro-mechanical linear actuators, which are configured to move grow light 4 in a linear direction toward or away from grow area 6 (e.g., motion in a vertical direction). In some embodiments, the extension or contraction of the one or more struts 16 may be achieved manually by an operator. In some embodiments, the extension or contraction of the one or more struts 16 is controlled by a control system configured to adjust the position of grow light 4 relative to grow area 6 based on one or more parameters. The one or more parameters may include, for example, time of day, season, plant surface temperature, surrounding air temperature, moisture level, plant type, plant height, chemical levels in plants 2, stage of growth of plants 2, carbon dioxide levels, oxygen levels, light reflectance off of plants 2.

In some embodiments, lighting system 10 may include one or more sensors for sensing the one or more parameters (e.g., light reflectance off of plants 2, gas levels, temperature, etc.), and the one or more sensed parameters may be used by the control system to adjust the position of grow light 4. In some embodiments, the one or more sensed parameters may be compared to predetermined threshold values, and based on such a comparison, the control system may lower or raise grow light 4 relative to grow area 6 and plants 2. For example, in some embodiments, if a temperature, light reflectance, and/or certain gas levels (e.g., carbon dioxide levels) at grow area 6 or plants 2 is sensed to be higher than predetermined threshold values, the control system may be configured to increase the distance between grow light 4 and grow area 6 (e.g., by causing one or more struts 16 to retract and raising grow light 4). On the other hand, if the sensed levels are below the predetermined threshold values, the control system may be configured to decrease the distance between grow light 4 and grow area 6 (e.g., by causing one or more struts 16 to extend and lowering grow light 4).

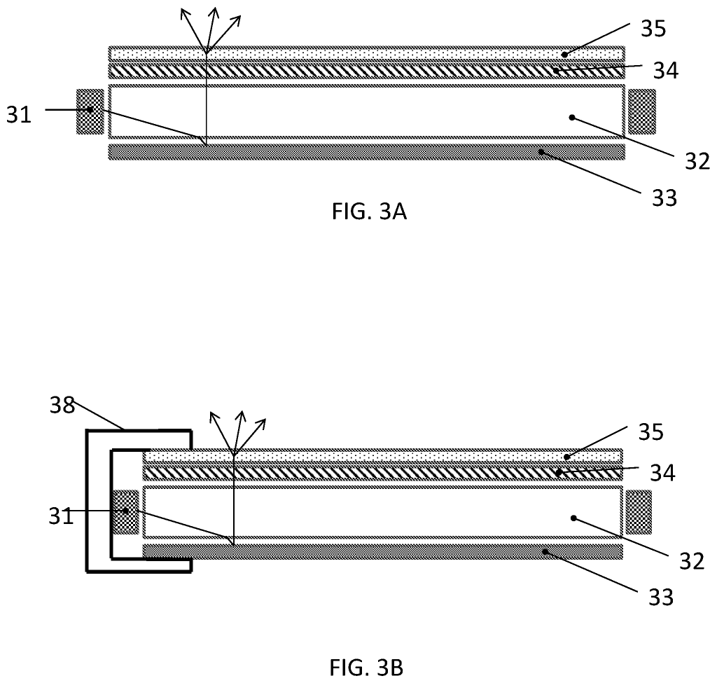

FIG. 3A illustrates an example of an edge-lit lighting source that can be used as a grow light, in accordance with an embodiment of the present disclosure. In this embodiment, the light panel 300 comprises a light guide 32 that is edge-lit by one or more light sources 31, an opaque reflector 33 that directs light to be emitted by the light panel through the light guide, and an energy conversion film 34 that converts light emission of short wavelengths, such as those emitted by the one or more light sources 31 to one or more longer wavelengths. An example illumination system comprising an illuminations source, a waveguide, and one or more energy conversion films have been described in U.S. Pat. Nos. 8,415,642 and 8,664,624, which are incorporated herein by reference in their entirety.

In some embodiments, the light source is disposed inside a U-shaped bracket or side-channel 38, which is disposed inside the frame, as shown in FIG. 3B. In such embodiments, the relative position of the light source and the other optical components including the light guide panel, the energy conversion film, the diffuser, the reflector, etc. can be fixed. The energy conversion film, in such embodiments, can be positioned between the light source and the corresponding edge of the light guide panel or over the front face of light guide panel.

In some embodiments, the one or more light sources 31 can be LEDs, e.g., blue LEDs that emit light having a spectrum substantially in the range of 440-495 nm. In some embodiments, at least one LED 31 is mounted to a carrier such as a rigid, flexible, or semi-flexible printed circuit board to form an LED strip that can be mounted to an interior edge of fixture frame surrounding the light guide 32. For example, in an embodiment, LED strip 31 may include seven LEDs arranged in a single row with a fixed distance between each LED 31. It should be appreciated that any number and/or color of LEDs, arranged on a variety of carriers in a variety of circuit configurations (e.g., series-connected LEDs, parallel-connected LEDs) can be used without departing from the scope of the technology.

As used herein, the term substantially means at least 80% within the given range. For example, in an embodiment where an emission spectrum is substantially in the range of 440-495 nm, at least 80% of the energy of the emitted light is provided by photons with wavelength within the range of 440-495 nm.

In some embodiments, LED 31 comprises a lens, such as a domed lens or a flat lens. In the structure shown in FIG. 3, a flat-top lens is preferable to enable a flush contact between the light guide 32 and the LED 31. For example, a domed lens in LED 31 may limit the number of photons that can be injected into the light guide 32 by limiting the proximity between the LED 31 and the light guide 32. In some embodiments, LED 31 comprises a flat-top lens and the lighting device 300 is configured to obtain greater than 90% efficiency of capture of light emitted from the LED 31 into the light guide 32. In some embodiments, LED 31 comprises a flat-top lens and the lighting device 300 is configured to obtain greater than 60% efficiency of capture of light emitted from the LED 31 into the light guide 32.

In some embodiments, at least one light injection optic (not shown) is optionally positioned between LED 31 and an edge of light guide panel 32 to direct light emitted from LED 31 into light guide panel 32 more efficiently than in conventional LED panel lighting systems. For example, light injection optic can be a cylindrical lens or other refractive optic capable of directing light emitted by LED 31 into light guide panel 32 at angles that facilitate the light being guided out of front face rather than escaping near an edge of light guide panel 32. In some embodiments, a light injection optic directs light emitted by LED 31 into light guide panel 32 by collimating or focusing light emitted by LED 31 into light guide panel 32.

In some embodiments, when included, the at least one light injection optic is mounted to a carrier to form a light injection strip (not shown) that can be respectively mounted between LED strip and edge of light guide 32. The light injection strip, when present, includes a number of light injection optics that is the same as the number of LEDs 31 on LED strips respectively (e.g., seven), which may be arranged in a single row with a fixed distance between each light injection optic. The fixed distance between each light injection optic is chosen to substantially align one light injection optic with each LED 31 of an LED strip. In some embodiments the light injection optics are molded into edges of light guide panel 32. Alternatively, such a light injection optic can be designed as a lens (e.g. a cylindrical lens) that acts on two or more LEDs. In still another embodiment, such a light injection optic can be designed as a single lens (e.g. a cylindrical lens) that acts collectively on the array of LEDs 31 arranged near the edge of the light guide 32 to inject light from the LEDs into the light guide 32.

In some embodiments, the use of a light injection optic including a refractive optical component between LEDs 31 and the edge of light guide panel 32 may increase the distance between the LED 31 and the edge of the light guide panel 32. In some such embodiments, whether or not the refractive optical component should be included can be determined by considering the angle of dispersion of the primary light emission from the LEDs. If the angle of dispersion of the LEDs is sufficiently acute, e.g., about 160° or less, about 140° or less, about 120° or less, or about 100° or less, a smaller distance between the LEDs and edge of the light guide is preferred, such that no refractive optical component would be positioned between the LED and the edge of the light guide panel. In some embodiments the preferred distance between the LED and the edge of the light guide is about 10 mm or less, about 5 mm or less, about 2 mm or less, about 1 mm or less, about 0.75 mm or less, about 0.5 mm or less, about 0.25 mm or less, about 0.1 mm or less, or about 0.05 mm or less. In some embodiments the preferred distance between the LED and the edge of the light guide is about 0.1 mm to about 5 mm, about 0.1 mm to about 2 mm, about 0.1 mm to about 1 mm, about 0.01 mm to about 1 mm, about 0.01 mm to about 0.05 mm, or about 0.01 mm to about 0.1 mm.

In an embodiment, light guide 32 is a rectangular panel formed of a transparent or translucent material such as acrylic, glass or quartz, configured to distribute and emit light emitted by LEDs 31. For example, light guide 32 is positioned in fixture frame such that edges of the frame are substantially adjacent to the light emitted by LEDs 31. Light emitted from LEDs 31 enters edges of the light guide 32 and is distributed throughout light guide 32. The light guide 32 typically incorporates a pattern of features designed to scatter guided optical modes of light transmission such that they are emitted from a front face of light guide 32 (i.e., the face of the light guide 32 adjacent the energy conversion film 34 to provide illumination.

In some embodiments, a pattern of features is provided by surface deformation, such as etching. In other embodiments, a pattern of features is provided by embossing, molding, or otherwise including discrete prismatic structures within the light guide 32. In still other embodiments, a pattern of features is provided by printing a thin layer of coating material onto the desired areas of the light guide 32. The coating material may have substantially the same refractive index as the light guide panel 32 and one or more light scattering materials substantially dispersed therein. In some embodiments the preferred distance between the LED and the edge of the light guide is about 10 mm or less, about 5 mm or less, about 2 mm or less, about 1 mm or less, about 0.75 mm or less, about 0.5 mm or less, about 0.25 mm or less: about 0.1 mm or less, or about 0.05 mm or less. In some embodiments, the preferred distance between the LED and the edge of the light guide is about 0.1 mm to about 5 mm, about 0.1 mm to about 2 mm, about 0.1 mm to about 1 mm, about 0.01 mm to about 1 mm, about 0.01 mm to about 0.05 mm, or about 0.01 mm to about 0.1 mm.

Opaque reflector 33 is formed of a reflective film or foil, and redirects any light emitted from a rear face of light guide 32 toward front face. An intimate contact between the opaque reflector 33 and the back surface of light guide 32 (side farther from viewer) is preferred. The opaque reflector 33 can be attached to the back surface of the light guide 32 by applying a thin and/or fine line of non-absorbing adhesive running along the circumference of the back surface of the light guide 32. The adhesive should be selected to not interfere with light guide panel extraction patterns. In some embodiments, the opaque reflector 33 is made from a material having a high glass transition temperature and able to withstand high temperatures (e.g., at least 120° C. or preferably at least 150° C.).

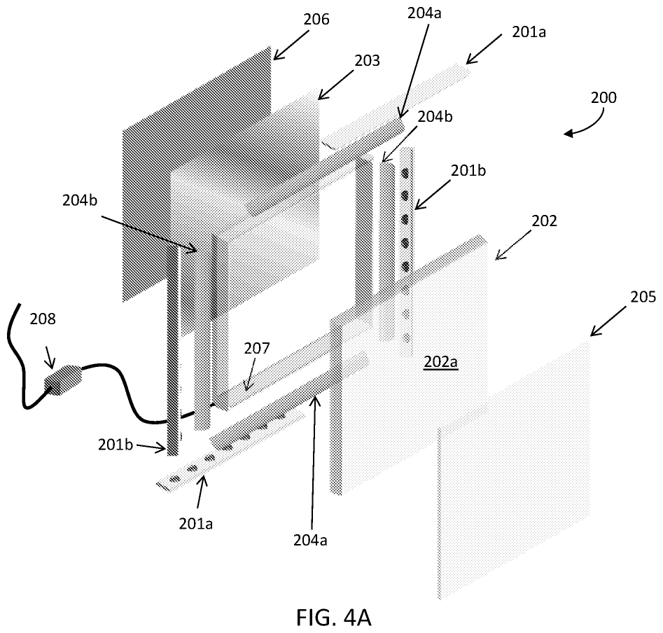

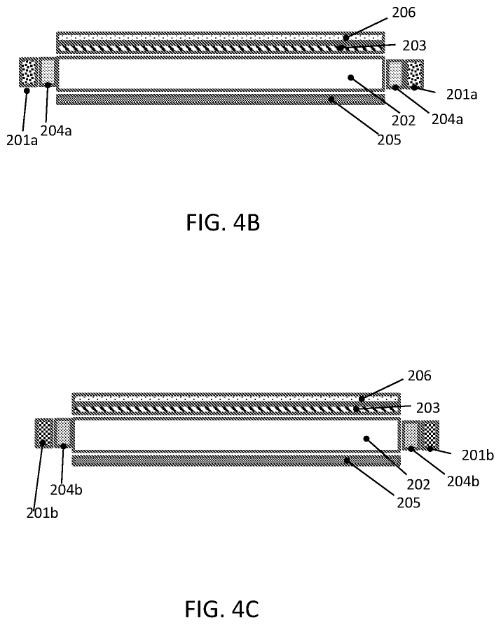

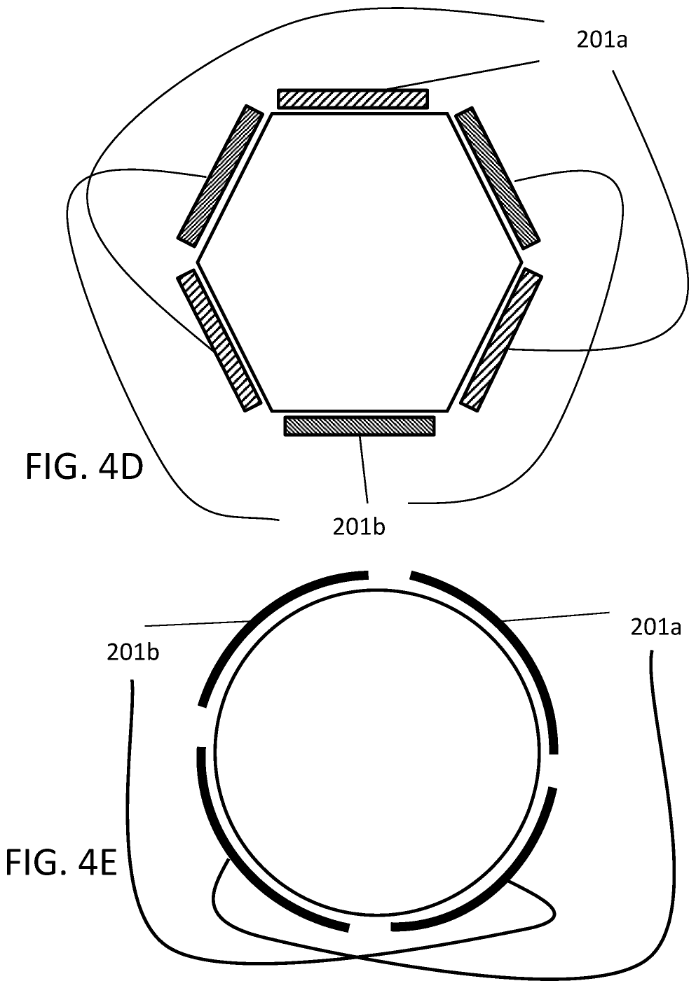

In some embodiments, the energy conversion film 34 is positioned in front of front face of light guide panel 32, while in other embodiments, the energy conversion film 34 is positioned between the LEDs 31 and the corresponding edge of the light guide panel 32 (see, e.g., FIG. 4A). The energy conversion film 34 is configured to convert the wavelength of the light emitted from LEDs 31 into one or more wavelengths of light that will be emitted from light panel. For example, the energy conversion film 34 can convert light having a substantially blue color to light having a substantially white color. In other embodiments, the energy conversion film 34 can convert light having a substantially blue color to light having a substantially green, yellow, orange, and/or red color. The energy conversion film 34 can be rendered as a cast, coated, injection-molded, or extruded sheet, planar or otherwise, generally including one or more layers comprising one or more photoluminescent (e.g. phosphorescent or fluorescent) materials such as organic fluorescent dyes. In some embodiments, energy conversion film 34 is an energy conversion structure according to embodiments described in U.S. Pat. Nos. 8,415,642 and 8,664,624, the contents of which are incorporated herein by reference in their entireties.

The matrix into which the fluorescent components of the ECF are dispersed can comprise of polymers or glasses. Polymers are particularly useful due to the greater range of available materials from which to sub-select so as to form a homogeneous mixture of the energy conversion element and the polymer. Acceptable polymers include acrylates, polyurethanes, polycarbonates, polyvinyl chlorides, polystyrene, silicone resins, and other common polymers. Materials with glass transition temperatures above the normal operating temperature of the material are particularly useful. In some embodiments, the polymer matrix must be capable of preventing aggregation of the fluorescent components that is creating a homogeneous mixture of the dye and the polymer, or a solid state solution of the dye in the polymer.

Fluorescent component aggregation is one of the possible causes of loss of fluorescence efficiency and in certain cases can also contribute to photolytic degradation. If the molecules of the fluorescent components are allowed to form aggregates and microcrystalline forms, instead of a solid state solution, the dye molecules excited by electromagnetic radiation can undergo static self-quenching, effectively lowering the yield of fluorescence, and therefore lowering the efficiency of energy conversion. In some fluorescent components, high concentrations can lead to enhanced photo-degradation, through efficient energy migration to chemically active traps or through self-sensitized photo-oxidation stimulated by triplet states accessed primarily from excimers.

The photoluminescent materials used in the energy conversion film 34 of the lighting system described herein are selected based on their absorption and emission properties, with preference given to materials with high quantum yields. In some embodiments, the energy conversion film 34 includes one or more photoluminescent (e.g. phosphorescent or fluorescent, in particular organic fluorescent) dyes. These dyes include, but are not limited to, rylenes, xanthenes, porphyrins, phthalocyanines, and others with high quantum yield properties. Rylene dyes are particularly useful. Rylene dyes include, but are not limited to, perylene ester and diimide materials, such as 3-cyanoperylene-9,10-dicarboxylic acid 2′,6′-diiosopropylanilide, 3,4,9,10-perylene tetracarboxylic acid bis(2,6-diisopropyl) anilide and 1,6,7,12-tetraphenoxy-N,N′-di(2,6-diisopropylphenyl)-3,4:9,10-perylenediimide for example. Xanthene dyes include, but are not limited to, Rhodamine B, Eosin Y, and fluorescein. Porphyrins include, for example, 5,10,15,20-tetraphenyl-21H,23H-tetraphenylporphine and 2,3,7,8,12,13,17,18-octaethyl-21H,23H-porphine.

For example, a photoluminescent (e.g. phosphorescent or fluorescent) dye may absorb blue light (e.g. in a range of about 450 nm to about 495 nm) and emit green light (e.g. in a range of about 495 nm to about 570 nm), yellow light (e.g. in a range of about 570 nm to about 590 nm), orange light (e.g. in a range of about 590 nm, to about 620 nm) and/or red light (e.g. in a range of about 620 nm to about 750 nm). In some embodiments, a photoluminescent (e.g. phosphorescent or fluorescent) dye may absorb green light (e.g. in a range of about 495 nm to about 570 nm) and emit yellow light (e.g. in a range of about 570 nm to about 590 nm), orange light (e.g. in a range of about 590 nm to about 620 nm), and/or red light (e.g. in a range of about 620 nm to about 750 nm). In some embodiments, a photoluminescent (e.g. phosphorescent or fluorescent) dye may absorb yellow light (e.g. in a range of about 570 nm to about 590 nm), and emit orange light (e.g. in a range of about 590 nm to about 620 nm) and/or red light (e.g. in a range of about 620 nm to about 750 nm). In some embodiments, a photoluminescent (e.g. phosphorescent or fluorescent) dye may absorb orange light (e.g. in a range of about 590 nm to about 620 nm) and emit red light (e.g. in a range of about 620 nm to about 750 nm). As used herein the term “about” refers to ±10% of the given value. For example, about 450 nm means within a range of 405-495 nm.

In some embodiments, a photoluminescent (e.g. phosphorescent or fluorescent) dye may have an absorption spectrum such that the photoluminescent (e.g. phosphorescent or fluorescent) dye can absorb more than one color of light. For example, in some embodiments, a photoluminescent (e.g. phosphorescent or fluorescent) dye may absorb light in a range of from about 380 nm to about 520 nm, about 380 nm to about 560 nm, or about 380 to about 600 nm.

In some embodiments, it is desirable that the energy conversion film 34 and/or light panel 300 produce full spectrum light. The generation of full spectrum light from a blue source (e.g., blue LED) entails the creation of green, yellow, and red spectral components from the blue source. The proper combination of these components can lead to white light, with the quality characteristics, such as correlated color temperature (CCT) and color rendering index (CRI) defined by the amount of each spectral component included in the combined spectrum. The dyes used in these constructions absorb incident light and emit their fluorescence isotropically (in all directions). These dyes do not absorb blue light equally, but can be part of an energy cascade to shift generally shorter wavelengths to longer wavelengths, with each shorter wavelength emission being absorbed, to some extent, by a dye responsible for a longer wavelength spectral component.

For example, as a result, green light, generated by a green-emitting dye, will have a tendency to be absorbed by a yellow emitter to be converted to yellow light. Such conversion will in turn reduce the color temperature and adjust the spectral power distribution of the emitted light. In preferred embodiments, color quality management can be handled by separating the conversion dyes, for example, such that the green and red color emitters are placed in a separate layer, or such that green and red color emitters are placed together in a layer separate from a yellow color emitter. In particular, it is preferred that green and red color emitters are placed closer to the viewer (farther from the blue light emitting diode source), with the yellow emitting dye being placed closer to the source. In this way, the distribution of green light into the viewing hemisphere can be maximized.

Accordingly, the spectrum of light emitted from light panel 300 can be controlled by separating some or all of the photoluminescent (e.g. phosphorescent or fluorescent) components into separate layers, and/or separating photoluminescent (e.g. phosphorescent or fluorescent) components from other dyes and/or pigments that can absorb light emitted from the light emitting diode or other photoluminescent (e.g. phosphorescent or fluorescent) components within the energy conversion sheet into separate layers. In some embodiments, lower wavelength spectral components may be optimized by separating the color changing components so that the photoluminescent (e.g. phosphorescent or fluorescent) components (and other dyes and/or pigments) that absorb such lower wavelength spectral components are positioned behind (e.g. closer to the light guide panel 32) another layer of the energy conversion film 34 that contains photoluminescent (e.g. phosphorescent or fluorescent) components that absorb high wavelength spectral components.

In some embodiments, where the energy conversion film 34 comprises more than one layer, one of a first layer and a second layer can include dyes that emit green light, such as diisobutyl 4,10-dicyanoperylene-3,9-dicarboxylate, fluorescein, and Coumarin 6. In some embodiments, where the energy conversion film 34 comprises more than one layer, one of a first layer and a second layer can include dyes that emit red light, such as 1,6,7,12-tetraphenoxy-N,N′-di(2,6-diisopropylphenyl)-3,4:910-perylene-diimide and 5,10,15,20-tetra(9,9-dihexyl-9H-fluoren-2-yl)porphyrin. In some embodiments, where the energy conversion film 34 comprises more than one layer, one of a first layer and a second layer can include one or more dyes that emit green light such as diisobutyl 4,10-dicyanoperylene-3,9-dicarboxylate, fluorescein, and Coumarin 6, and one or more dyes that emit red light, such as 1,6,7,12-tetraphenoxy-N,N′-di(2,6-diisopropylphenyl)-3,4:910-perylene-diimide and 5,10,15,20-tetra(9,9-dihexyl-9H-fluoren-2-yl)porphyrin.

In some embodiments, where the energy conversion film 34 comprises more than one layer, one of a first layer and a second layer can include dyes that emit yellow light, such as 3-cyanoperylene-9,10-dicarboxylic acid 2′6′-diisopropylanilide and Eosin Y. In some embodiments, where the energy conversion film 34 comprises more than one layer, one of a first layer and a second layer can include one or more dyes that emit green light, such as diisobutyl 4,10-dicyanoperylene-3,9-dicarboxylate, fluorescein, and Coumarin 6, and one or more dyes that emit red light, such as 1,6,7,12-tetraphenoxy-N,N′-di(2,6-diisopropylphenyl)-3,4:910-perylene-diimide and 5,10,15,20-tetra(9,9-dihexyl-9H-fluoren-2-yl)porphyrin, while the other of a first layer and a second layer can include one or more dyes that emit yellow light, such as 3-cyanoperylene-9,10-dicarboxylic acid 2′6′-diisopropylanilide and Eosin Y. The foregoing embodiments are provided as examples of layering of different types of photoluminescent (e.g. phosphorescent or fluorescent) dyes within energy conversion film 34; other combinations of layers comprising different dyes are within the scope of the disclosure.

In a specific embodiment, a lighting device comprises the energy conversion sheet comprising a first layer comprising diisobutyl 4,10-dicyanoperylene-3,9-dicarboxylate and 1,6,7,12-Tetraphenoxy-N,N′-di(2,6-diisopropylphenyl)-3,4:910-perylene-diimide, and a second layer 122b comprising 3-cyanoperylene-9,10-dicarboxylic acid 2′6′-diisopropylanilide. Another example is an energy conversion sheet comprising a single layer of 3-cyanoperylene-9,10-dicarboxylic acid 2′6′-diisopropylanilide and diisobutyl 4,10-dicyanoperylene-3,9-dicarboxylate. In another example, Coumarin 6 and manganese-doped strontium aluminate phosphor are combined in a single layer.

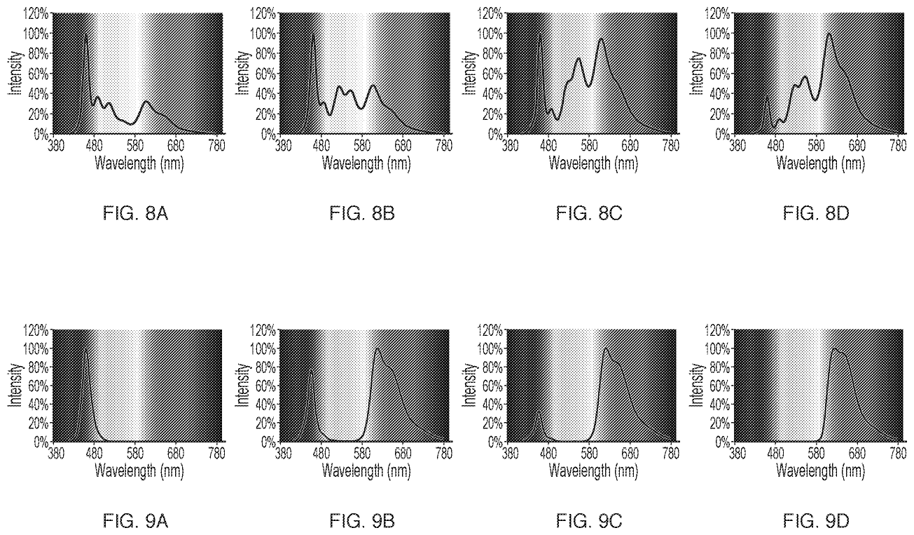

In some embodiments, it may be desirable for the growth of plants 2 that energy conversion film 34 is selected to produce full spectrum white light. In some embodiments, where full spectrum white light is desired, energy conversion film 34 is configured to generate white light with different CCT and blue content. In some embodiments, it has been found that light in the cool white spectrum 7000-15000K with high blue content (i.e., spectral power distribution with about 30% to about 70% power being centered between about 430 nm and about 480 nm) promotes leaf growth (vegetation), while a warm white spectrum with high yellow/red content is beneficial for plants in a flowering stage. FIGS. 8A-8D illustrate example spectra achievable using different energy conversion films 34, where FIGS. 8A-8C show high blue content and increasing yellow/red content, and FIG. 8D shows low blue content and high yellow/red content.

In some embodiments, it has been found that providing plants only blue and red light produces yields as high as a full spectrum (e.g., white) grow light. Thus, in some embodiments, light panel 100 may be configured to produce light that has low or no green light content. In further embodiments, it has been found that different blue to red ratios can be tailored for different plant growth stages and for different plant species. For example, for strawberry and tomatoes, optimal spectral power distribution is: 16% blue centered at 450 nm, 24% of the light should be centered at 530, and 50% of light should be between 625 nm and 700 nm centered at 660 nm. We will also want about 10% of light output to be above 700 nm. In another example, cannabis require 18% blue centered at 450 nm, 28% of the light should be centered at 530, and 46% of light should be between 625 nm and 700 nm centered at 660 nm. In various embodiments, it may be desirable to have about 10% of light output to be above 700 nm. In some embodiments, higher blue to red ratios promote shorter stems and bigger leaves (vegetation) while in some embodiments lower blue to red ratios promotes budding (flowering). In some embodiments, energy conversion film 34 is configured to produce blue and red light in a ratio from 1:0 to 0:1 by peak intensity. FIGS. 9A-9D illustrate example spectra having different blue to red peak intensity ratios achievable using different energy conversion film 34, where FIG. 9A shows a blue to red peak intensity ratio of about 1:0, FIG. 9B shows a blue to red peak intensity ratio of about 0.8:1, FIG. 9C shows a blue to red peak intensity ratio of about 0.35:1, and FIG. 9D shows a blue to red peak intensity ratio of about 0:1.

In an embodiment, the energy conversion film additionally includes from about 25%-45% of binder resin, about 50%-70% of liquid carrier, 0%-2% dispersing agent, 0%-2% rheology modifying agent, 0%-2% photostabilizer, 0%-2% de-aerating agent, 0%-2% wetting agent, and 0.01%-0.2% photoluminescent fluorescent material.

The energy conversion film may also comprise a carrier medium. The carrier medium may be rigid glass, such as a borosilicate or quartz glass, or may be a polymeric carrier such as an acrylic resin, a polyvinyl chloride, a polycarbonate, a styrene, a polyurethane, a polyester, or other similar polymer. Depending on the nature of the preparation of the energy conversion film, the carrier may include other components such as antioxidants, surfactants, hindered amine light stabilizers (HALS), and other similar additives.

In some embodiments, energy conversion film further includes materials to optically scatter the light emitted into energy conversion film by light guide panel 32 and/or the converted light that is ultimately emitted from energy conversion film. The scattering of the light can increase the effective optical path length of the energy conversion film thereby increasing the amount of light that is absorbed and converted to a desired wavelength. For example, the scattering of the emitted light serves to alter the path of emitted light rays that would otherwise be emitted from the edges of the energy conversion film due to total internal reflection.

In some embodiments, light panel 100 may optionally include a stability enhancement layer. Exemplary stability enhancement layers are described in U.S. Pat. No. 8,664,624 to Kingsley, et al., which is incorporated by reference herein. Stability enhancement layer, in some embodiments, may protect the photoluminescent materials of the energy conversion film from light-induced (photolytic) degradation and/or thermal degradation, so as to provide sustained emissions. In some embodiments, the stability enhancement layer can be rendered as a discrete layer. While this may be preferable in some embodiments, it should be recognized that some functionality of the stability enhancement layer can also be achieved within the energy conversion film itself by suitable selection of the polymer matrix of the energy conversion film. In certain applications it is advantageous to have a stability enhancement layer on both sides of the energy conversion film.

In some embodiments a polymer for use in a stability enhancement layer is thermally stable. Generally, it is advantageous to select a polymer which glass transition temperature is higher than the expected operating temperature of the system. In some embodiments it would be desirable to select a polymer with a glass transition temperature that is 10° C. to 15° C. higher than the operating temperature of light panel 100 (e.g., at least 120° C. or preferably at least 150° C.). In some embodiments a polymer for use in a stability enhancement layer is photolytically stable. Specifically, materials that are known to significantly retard the diffusion of oxygen may have a dramatic impact on improving photolytic stability.

To extend the stability of the photoluminescent materials, in some embodiments stability enhancement layer includes, for example, a number of materials commonly used today to inhibit the transmission of air, especially in applications such as food packaging. Such materials include, but are not limited to, polyvinyl alcohol, ethylene vinyl alcohol copolymers, polyvinyl chloride, polyvinylidene chloride copolymers (saran), nylons, acrylonitriles, polyethylene terephthalate polyester, polyethylene naphthalate, polytrimethylene terephthalate, liquid crystal polymers, transparent inorganic oxide coatings, nanocomposites, oxygen scavengers, aromatic polyketones and any combinations or blends thereof. Such materials may be used in a discrete stability enhancement layer and/or incorporated into energy conversion film.

In certain situations, it is advantageous to have the stability enhancement layer on both the front and rear surfaces of the energy conversion film. One of the preferred ways of achieving that is to create a stability enhancement layer that inhibits the transmission of oxygen on one side of the energy conversion film, for example on the side of the converted emission emitting surface, and for the other side the reflection layer. The low diffusion of oxygen through the reflective sheet (e.g. metal oxide layers) may serve as an effective second stability enhancement layer in this case. It should also be noted that for certain applications, a suitably thick polyester substrate onto which are rendered the energy conversion layer and the stability enhancement layer can also provide some functionality in retarding the diffusion of oxygen from the opposite side.

Singlet molecular oxygen is presumed to be an important reactive species in the photolytic degradation of dyes. While reducing the concentration of oxygen is an effective deterrent to the creation of singlet oxygen, this species can also be quenched by a number of additives, thereby preventing it from reacting with the photoluminescent dye. In some embodiments such quenchers may be placed in the layer in which the singlet oxygen is most readily formed, that is in the energy conversion film. Examples of singlet oxygen quenchers that may be included in energy conversion film and/or stability enhancement layer include, but are not limited to, 2,2,6,6-tetramethyl-4-piperidone, 1,4-diazabicyclo[2.2.2]octane, and diphenylsulfide.

In some embodiments, a diffuser sheet 35 is positioned in front of stability enhancement layer, such that stability enhancement layer is sandwiched between energy conversion film and diffuser sheet. In some embodiments, diffuser sheet 35 is configured to increase optical scattering of at least a portion of the light emitted from light guide panel 32. In some embodiments, diffuser sheet 35 may include one or more light scattering materials. In some embodiments, diffuser sheet 35 includes a patterned diffuser, e.g., a patterned plastic diffuser having a patterned surface configured to provide optical homogenization. Preferably the diffuser sheet 35 is constructed from a material with a high glass transition temperature (e.g., at least 120° C. or preferably at least 150° C.). In some embodiments, diffuser sheet 35 may be constructed from polycarbonate, transparent ABS (Acrylonitrile Butadiene Styrene), and/or polyphenylene oxide according to some examples.

In some embodiments, the energy conversion film are polymeric films including one or more dyes, phosphors, or pigments. The one or more dyes, phosphors, pigments, etc. are generally homogeneously distributed within the body of the films.

The light panel may also comprise additional optical components to efficiently direct and disperse the light generated into a useful spatial pattern. In particular, at least one reflector may be used to direct light to a preferred viewing hemisphere. Additionally, light emitted from the front face of the light panel can be dispersed using one or more diffusers, lenses, prisms, or other more complex optical components.

In some embodiments, light panel 32 may be configured such that one energy conversion film 34 may be substituted with another energy conversion film 34 that produces a different spectrum of light. This may allow the spectrum to be customized in order to optimize yield for different plants and/or different growth phases. For example, in some embodiments, a first energy conversion film 34 which produces a high blue to red ratio may be replaced with a second energy conversion film 34 which produces a lower blue to red ratio (e.g., in order to promote flowering) or vice versa (e.g., in order to promote vegetation growth). Similarly, in other example embodiments, a first energy conversion film 34 which produces a full spectrum having high blue content may be replaced with a second energy conversion film 34 which produces a full spectrum having higher yellow/red content (e.g., in order to promote flowering), or vice versa (e.g., in order to promote vegetation growth). Replacement of energy conversion film 34 is preferably achievable without having to remove the entire light panel 32 from lighting system 10 or without needing to remove light panel 32 form support.

In some embodiments, switching of energy conversion film 34 may be controlled by a control system based on a predetermined algorithm. In some embodiments, a lighting system may be programmed such that the grow lights 4 provide the plants 2 a certain light intensity level for a predetermined amount of time and spectrum at a particular growth stage. For example, 22 hours of vegetation spectrum (e.g., high blue content) +2 hours dark daily for the vegetation stage and 12 hours flowering spectrum (e.g., high yellow/red content) +12 hours dark daily for flowering stage. In some embodiments, a lighting system may include one or more sensors configured to detect the plants' responses to lighting (e.g., CO₂ level, temperature, reflectance etc.) and create a feedback loop/algorithm to control the output light spectra and intensity from grow lights 4.

Edge-Lit Embodiments

One way of obtaining different output spectra from the light panel 300 is to provide two types of light into the light panel 300, for example, by providing an appropriate energy conversion component with an appropriate LED source at the entrance face of the light into the edge of the light guide. Each of these energy conversion components comprises one or more fluorescent components uniformly incorporated into a block or slab of polymer or glass in concentrations useful to generate the desired converted spectrum when illuminated by the appropriate source light. The block or slab may additionally be covered on at least two sides with a reflective element or coating to direct the light toward the injection face of the light guide. The block or slab may also be covered on at least two sides with a protective film or coating to inhibit the penetration of oxygen into the energy conversion component. Additionally, the block or slab may be covered with a directional reflective film or coating on the side immediately adjacent to the edge of the light guide, to prevent the excitation of dyes by the “wrong” set of LEDs. For example, it would be undesirable for the daytime LED source to activate the nighttime energy conversion component, and vice versa (i.e., LEDs 201b activating 204a in FIG. 4A, described in detail elsewhere herein).

FIGS. 4A-4C each show a lighting device 200 (or grow light) according to an example embodiment of the present disclosure which can provide light that has either high blue content (e.g., vegetation spectrum) or high yellow/red content (e.g., flowering spectrum). In some embodiments, lighting device 200 includes a light guide panel 202 which is configured to be edge-lit by at least two separate sets of LEDs, a first set which is configured to provide the source light to produce the light with high blue content and a second set which is configured to provide the source light to produce the light with high yellow/red content. Light guide panel 202, in some embodiments, may be shaped as a generally square panel as shown having a square light emitting surface 202a. In some embodiments, the first set of LEDs includes two LED strips 201a that may be positioned along a first pair of opposing edges of light guide panel 202 and the second set of LEDs includes two LED strips 201b that may be positioned along a second pair of opposing edges of light guide panel 202.

In some embodiments, LED strips 201a and LED strips 201b are configured to emit different wavelengths of light. For example, in some embodiments, LED strips 201a include LEDs which emit light with a peak emission at 445-475 nm, while LED strips 201b include LEDs which emit light with a peak emission at 640-660 nm. In some embodiments, the one of the LED strips 201b includes LEDs which emit light with a peak emission at 640-600 nm and one of the LED strips 201b includes LEDs which emit light with a peak emission at 700-780 nm. In some embodiments, the light guide panel 202 is configured by one set of LEDs configured to emit light with a peak emission at 400-460 nm. In such embodiments, the two LED strips 201a and 201b both include LEDs configured to emit light with a same peak emission at 400-460 nm.

In some embodiments, at least one energy conversion film (ECF) is positioned between each of LED strips 201a, 201b and the edges of light guide panel 202. In some embodiments, the at least one energy conversion film includes first ECF strips 204a positioned between LED strips 201a and a corresponding edge of the light guide panel 202, and second ECF strips 204b positioned between LED strips 201b and light guide panel 202. In some embodiments, first ECF strips 204a are configured to convert at least a portion of a spectrum emitted by LED strips 201a into a first converted spectrum with, for example, a high blue content and a CCT of 9000-15000 K. In some embodiments, second EFC strips 204b are configured to convert at least a portion of a spectrum emitted by LED strips 201b into a second converted spectrum with, for example, a high yellow/red content and a CCT of 2000-5000 K and a red/yellow content in a range from about 50% to about 85% (i.e., spectral power distribution of between 50 and 85% in the red/yellow region). In some embodiments, EFC strips 204a contains a different fluorescent dye composition and/or amount than EFC strips 204b in order to achieve the different spectral composition.

In further embodiments, lighting device 200 may further include a reflecting layer 203 configured to be positioned to face a back surface of light guide 202 that is opposite light emitting surface 202a. Reflecting layer 203 in some embodiments is configured to reflect at least a portion of light towards light emitting surface 202a. Lighting device 200 may also include a diffusion layer 205 configured to be positioned on light emitting surface 202a and configured to scatter light emitted from light emitting surface 202a. Light guide panel 202 may therefore be positioned between reflecting layer 203 and diffusion layer 205. In still further embodiments, lighting device 200 may include a backing layer 206 positioned behind reflecting layer 203 such that reflecting layer 203 is positioned between backing layer 206 and light guide panel 202. In some embodiments, frame 207 may be provided to house components of lighting device 200, including light guide panel 202, LED strips 201a, 202b, and ECF strips 204a, 204b. In some embodiments, LED strips 201a, 201b may be mounted along the internal edges of frame 207. In further embodiments, frame 207 may be made of metal (e.g., aluminum, copper, etc.), for example, and be configured to help dissipate heat from LED strips 201a, 202b.

The dimensions of the lighting device 200 are not particularly limited and are determined by factors such as, for example, design constraints based on the space in which the lighting device (e.g., size of the grow box) is to be used, materials being used to construct various components of the lighting device, commercial availability or manufacturability of some or all of the components of the lighting device, etc. Common dimensions of such devices may include, without limiting the scope of this disclosure, 1′×1′, 2′×2′, 3′×3′, 1′×4′, and 2′×4′.

It will be appreciated that while examples with a square shaped edge-lit grow light are discussed herein, other regular polygonal shapes such as, for example, hexagon, octagon, etc. can be implemented with modifications based on an understanding of the concepts disclosed herein. Similarly, a circular grow light may also be implemented. Examples of a hexagonal edge-lit grow light and a circular edge-lit grow light are shown in FIGS. 4D and 4E (which show the plan view of the hexagonal and circular grow light respectively). It must be noted that while only the LED strips 201a/201b are shown in FIGS. 4D and 4E for convenience, each of the LED strips include the corresponding ECF as well. The circular geometry allows more than 2 types of spectra, e.g., using more than 2 types ECF configured to provide different output spectra. It must also be noted that while only two types of LED strips are shown in FIGS. 2D and 2E, more types of LED strips may be included. For example, FIG. 2D can include three different types of LED strips disposed on each pair of opposing edges of the light guide panel 202 while maintaining the symmetry. Likewise, in FIG. 2E, while only 2 pairs of LED strips are shown, any number (e.g., 1, 2, 3, 4, 5, 6, etc.) of pairs of LED strips can be disposed symmetrically opposite around the circumference of the light guide panel to potentially obtain the corresponding number of output spectra.

Some of the geometries such as the hexagonal or circular shapes allow more than 2 types of spectra, e.g., using more than 2 types ECF configured to provide different output spectra. Lighting devices with geometries that provide different (e.g., more than two) output spectra may be used for applications where more than two types of light spectra are desired for different stages of plant growth or at different times of the day. In such applications, the lighting devices may include more than two types of ECFs configured to provide more than two types of output spectra and the LED strips corresponding to each type of ECF may be selectively turned on at a desired time to provide the desired output spectrum. Such embodiments may, therefore, be used to tailor intensities of various wavelength ranges by separating different energy conversion elements into different film, rather than layering them onto a same energy conversion film. For example, where a higher intensity of a particular wavelength range is required, a separate energy conversion film including an energy conversion element generating that particular wavelength range may be provided to an LED strip along one of the edges, thereby increasing the relative weight of that particular wavelength range within the output spectrum produced by the lighting device as a whole.

In some embodiments, instead of the opaque reflector 203, a second diffuser 205′ (not explicitly shown) is provided in the lighting device 200. This allows for emission of light from the light guide panel 202 in both the front and the back directions. Advantageously, such embodiments may be used to reduce the number of grow lights in half by, for example, placing the grow light along a wall dividing two grow boxes.

In some embodiments, a continuous rolling sheet of energy conversion film may be positioned on the front face of the grow light (instead of the energy conversion film(s) being positioned statically on the LEDs or the front face of the grow light). For example, a roller on which an appropriately sized energy conversion film is wrapped is positioned adjacent the grow light, and the energy conversion film stretched over the front face of the grow light. In such embodiments, appropriately sized portions of the energy conversion film may have different compositions (e.g., combinations of photoluminescent materials) to provide different light spectra when exposed to the grow light. Thus, by rolling the roller, a different composition of the energy conversion film may be exposed to the grow light, thereby changing the output light spectrum. In such embodiments, the microcontroller may be programmed to appropriately control the roller instead of controlling the power supply. Advantageously, in such embodiments, any number of different compositions of energy conversion films can be provided. Moreover, in such embodiments, it is relatively easy to change the energy conversion films as their conversion efficiency decreases over time.

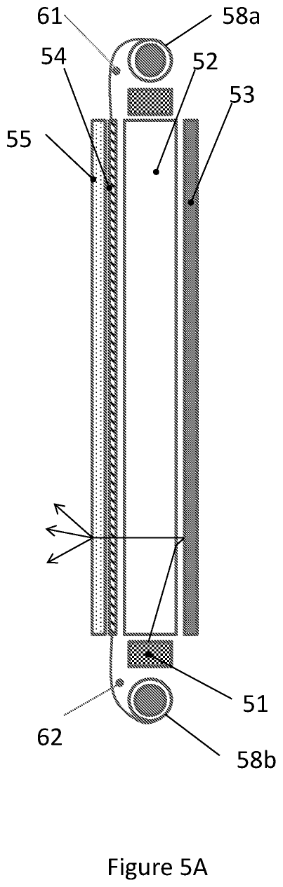

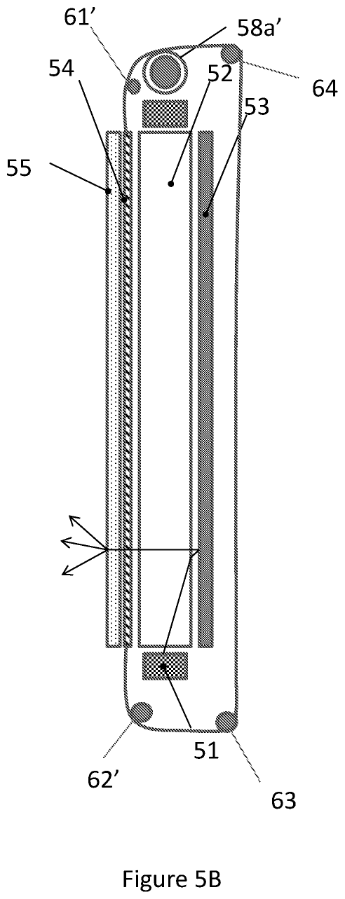

FIG. 5A shows an embodiment of a lighting device 500 including a mechanism 58 for changing the energy conversion component (film) 54. Various components of the lighting device 500 are essentially the same as those of the lighting device shown in FIG. 1, with the addition of the mechanism 58 for changing the energy conversion film 54. In an embodiment, as shown in FIG. 5A, the mechanism 58 includes a roller 58a on which the energy conversion firm (ECF) 54 is wrapped. A portion of the ECF 54 is stretched across the light guide panel 52. The portion of ECF 54 being stretched across the light guide panel 52 can be changed by turning the roller such that the ECF 54 moves across the light panel 52 to expose a different portion of the ECF 54 to the light guide panel 52. A counter-roller 58b may be included opposite the roller 58 to collect the portion of the ECF 54 that is moved away from the light guide panel 52.

Additionally, guide-rollers 61 and 62 may be included for guiding the ECF 54 along a track so as to prevent mechanical scraping of the ECF 54 and ensuring a smooth movement of the ECF 54 over the light guide panel 52. In such an embodiment, a slot (not shown) and a track (not shown) may be provided within the frame of the lighting device 500 for the ECF 54 to move in an out of the frame. In some embodiments, the roller 58a and counter-roller 58b may be provided with a rotating crank (not shown) to rotate the corresponding rollers manually so as to change the portion of ECF 54 being exposed to the light guide panel 52.

In other embodiments, the roller 58a and counter-roller 58b may be motorized, and the motor (not shown) may be powered through a switch allowing a user to rotate the roller 58a and the counter-roller 58b when desired. In yet other embodiments, the roller 58a and the counter-roller 58b may be motorized, and the motor is controlled using a controller which automatically initiates the rotation of the roller 58a and the counter-roller 58b based on a programmed scheduled to expose different portions of the ECF 54 to the light guide panel as desired. In some embodiments, movement of the ECF is created by friction between the ECF and the drive roller. In some embodiments, the movement of the ECF is created by a cog or similar spoked wheeled engaging holes, slots or other such physical characteristics on the ECF structure.

FIG. 5B shows an alternative mechanism for changing the portion of ECF 54 being exposed to the light guide panel 52. As shown in FIG. 5B, the alternative mechanism includes only one roller 58a′ and guide-rollers 61′, 62′, 63 and 64 which guide the ECF 54 to move over the light guide panel 52. In such an embodiment, the roller 58a′ may be provided with a crank (not shown), a motor with a switch or a motor with a controller similar to the embodiment disclosed elsewhere herein.

In the implementations where different portions of the ECF are exposed to the light guide panel as desired, the ECF may be formed as a continuous film with different portions having different compositions allowing each portion to output a different spectrum. For example, in an embodiment, the ECF may include a first portion configured to provide light with high blue content and a second portion configured to provide light with high red/yellow content. The ECF may be formed as continuous film with the first portion and the second portion alternately placed immediately adjacent to each other. In some embodiments, the first portion and the second portion are separated by a third portion without any energy conversion elements (e.g., dyes, fluorophores, phosphors, etc.). Additional portions with different ECF configurations are contemplated.

In some embodiments, the mechanism for changing the portion of ECF being exposed to the light guide panel may be controlled using a controller. The controller may be programmed in a manner discussed in detail elsewhere herein, e.g., to provide different light spectra based, e.g., on plant health or plant stage determined by measuring one or more parameters. For example, instead of adjusting the power supplied to different sets of LEDs provided with different ECFs, the roller 58a (and 58b or 58a′) may be rotated to expose different portions of ECFs to the light guide panel based on the plant health or plant stage.

Advantageously, such embodiments do not limit the number of different output spectra that can be produced using the grow light because different portions of the ECF may be provided with different sets of energy conversion elements that are composed to provide different spectra. Additionally, because all possible LEDs in the grow light can be used in such embodiments, the intensity of light emitted by the grow light can be substantially higher than in embodiments where LEDs along certain edges are used at a given time. Moreover, in such embodiments, it is relatively easy to change the ECF in instances where the ECF has been damaged or when the energy conversion elements within ECF have lost their ability to convert the wavelengths as desired, e.g., because of chemical changes occurring in the molecules of the energy conversion elements caused by, for example, oxidation.

Back-Lit Embodiments

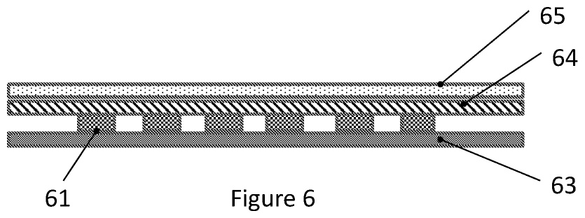

FIG. 6 illustrates an example of an edge-lit lighting source that can be used as a grow light, in accordance with an embodiment of the present disclosure. In this embodiment, the light panel 600 comprises one or more light sources 61 positioned on an opaque reflector 63 that directs light to be emitted by the one or more light sources to a viewing hemisphere, and an energy conversion film 64 that converts at least a portion of a first spectrum emitted by the light sources 61 into a second spectrum. In some embodiments, the light panel includes a diffuser 65 to disperse the light converted by the energy conversion film 64 into the viewing hemisphere. An example illumination system comprising one or more energy conversion films have been described in U.S. Pat. No. 8,415,642 and 8,664,624, which are incorporated herein by reference in their entirety.

Examples of incandescent sources include, without limitation, incandescent light bulbs, halogen lamps, various flash lamps, etc. Examples of electric discharge sources include, but are not limited to, arc lamps, flashtubes, mercury vapor lamps, sodium vapor lamps, metal-halide lamps, neon lamps, etc. Electroluminescent sources include, for example, light emitting diodes (LEDs), organic light-emitting diodes (OLEDs), various types of LASERs, etc. In various embodiments of the present disclosure, LEDs are used as light sources. It will, however, be understood that the lighting systems described herein can be suitably modified for use with other types of light sources.

In some embodiments, the light source is disposed inside a U-shaped bracket or channel, which is disposed on an opaque reflector inside the frame or heat sink, with light source facing towards the grow area. In such embodiments, the relative position of the light source and the other optical components including the energy conversion film, the diffuser, the reflector, etc.

In some embodiments, the one or more light sources 61 can be LEDs, e.g., blue LEDs that emit light having a spectrum substantially in the range of 440-495 nm. In some embodiments, at least one LED 61 is mounted to a carrier such as a rigid, flexible, or semi-flexible printed circuit board to form an LED strip that can be mounted to a back of fixture frame. For example, in an embodiment, LED strip 61 may include seven LEDs arranged in a single row with a fixed distance between each LED 61. It should be appreciated that any number and/or color of LEDs, arranged on a variety of carriers in a variety of circuit configurations (e.g., series-connected LEDs, parallel-connected LEDs) can be used without departing from the scope of the technology.

As used herein, the term substantially means at least 80% within the given range. For example, in an embodiment where an emission spectrum is substantially in the range of 440-495 nm, at least 80% of the energy of the emitted light is provided by photons with wavelength within the range of 440-495 nm.

Opaque reflector 63 is formed of a reflective film or foil, and redirects any light emitted from a rear face of the energy conversion component 64 or the diffuser 65 toward front face. An intimate contact between the opaque reflector 63 and the back surface of LED 31 (side farther from viewer) is preferred. The opaque reflector 63 can be attached to the back surface of the LED 61 by applying a thin and/or fine line of non-absorbing adhesive running along the circumference of the back surface of the LED 61.

The energy conversion film 64 in such embodiments is similar to the energy conversion film 34 used in the edge-lit luminaires discussed elsewhere herein. The same discussion as that related to the energy conversion film 34 is applicable to energy conversion film 64, and a detailed discussion about the energy conversion film 64 for the back-lit luminaires will, therefore, be omitted in interest of brevity.

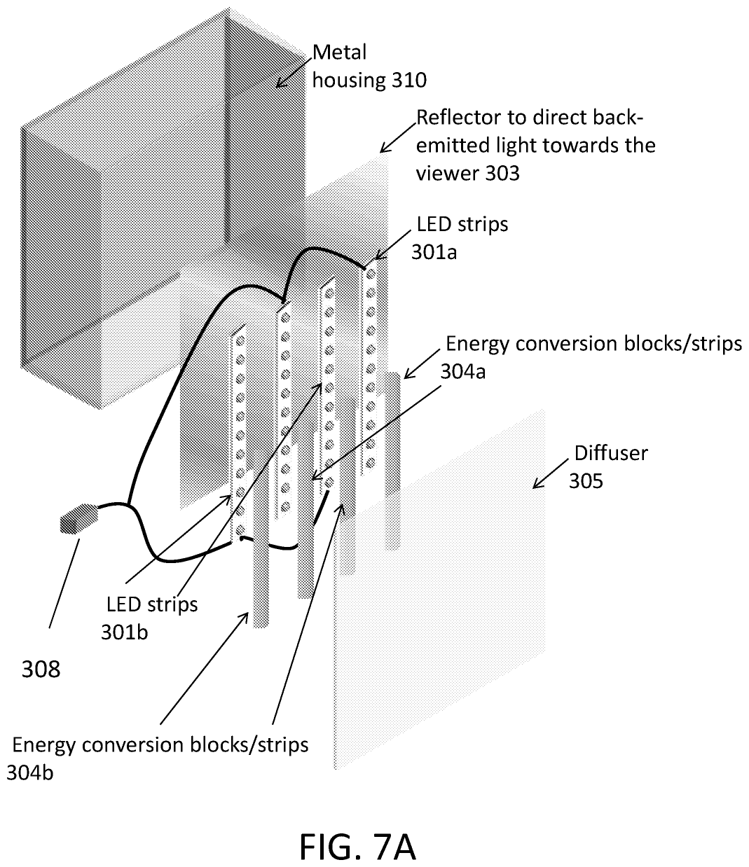

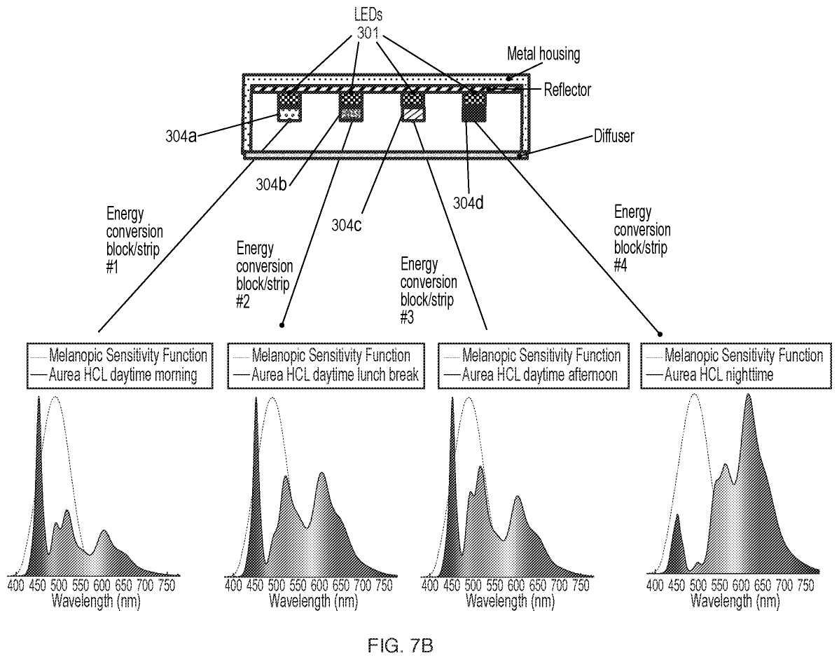

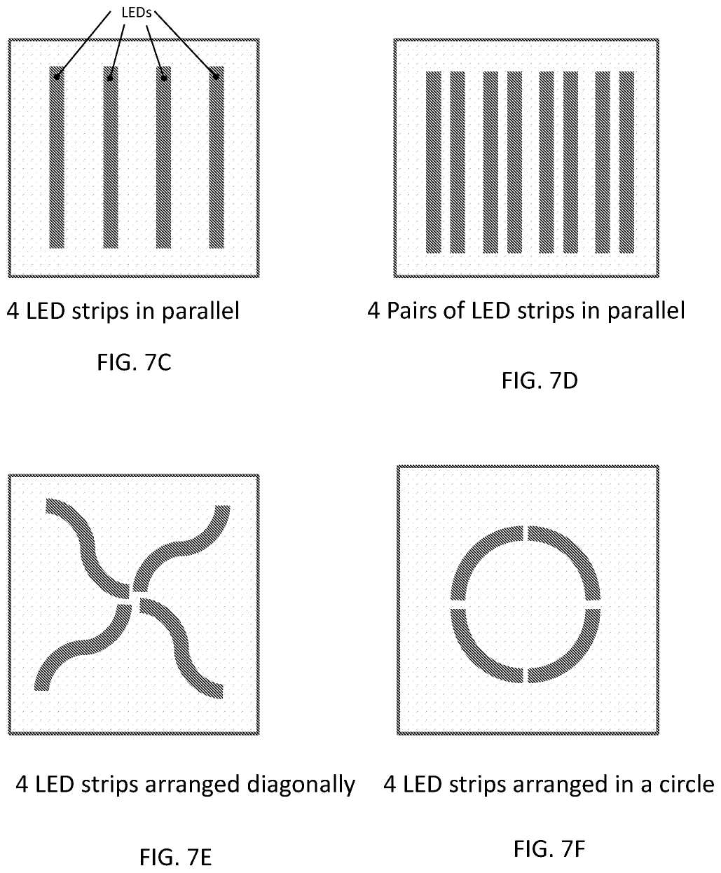

FIG. 7A schematically shows a back-lit luminaire in accordance with an implementation of the present disclosure. Such an implementation includes a metal housing 310, a reflector 303 at a far end (i.e., the end farthest away from a user) of the metal housing 310. LED strips 301 are placed adjacent the reflector 303. In some embodiments, lighting device 300 includes a first set 301a which is configured to provide the source light to produce the light with high blue content and a second set 301b which is configured to provide the source light to produce the light with high red/yellow. The first and second set 301a/301b are disposed on a reflector 303, configured to direct back-emitted light by the first and second sets toward the viewing hemisphere through the diffuser 305.

In some embodiments, LED strips 301a and LED strips 301b are configured to emit different wavelengths of light. For example, in some embodiments, LED strips 301a include LEDs which emit light with a peak emission at 445-475 nm, while LED strips 301b include LEDs which emit light with a peak emission at 640-660 nm. In some embodiments, two additional (not shown) LED strips 301 may be included with LEDs which emit light with a peak emission at 700-780 nm. In some embodiments, the two LED strips 301a and 301b both include LEDs configured to emit same wavelengths of light, e.g., with a same peak emission at 400-460 nm.

In some embodiments, at least one energy conversion film (ECF) is positioned between each of LED strips 301a, 301b and the back surface of the diffuser 305. In some embodiments, the at least one energy conversion film includes first ECF strips 204a positioned between each of the LED strips 301a and the back surface of the diffuser 305, and second ECF strips 304b positioned between each of the LED strips 301b and the back surface of the diffuser 305. In some embodiments, first ECF strips 304a are configured to convert at least a portion of a spectrum emitted by LED strips 301a into a first converted spectrum with, for example, a high blue content and a CCT of 9000-15000 K. In some embodiments, second ECF strips 304b are configured to convert at least a portion of a spectrum emitted by LED strips 301b into a second converted spectrum with, for example, a high yellow/red content and a CCT of 2000-5000 K and a red/yellow content in a range from about 50% to about 85% (i.e., spectral power distribution of between 50 and 85% in the red/yellow region). In some embodiments, EFC strips 304a contains a different fluorescent dye composition and/or amount than EFC strips 304b in order to achieve the different spectral composition.

The reflecting layer 303 in some embodiments is configured to reflect at least a portion of light towards the viewing hemisphere through the diffuser 305. In some embodiments, lighting device 300 may include a backing layer (not shown) positioned behind reflecting layer 303 such that reflecting layer 303 is positioned between backing layer 306 and the diffuser 305. In some embodiments, a frame or a metal housing 310 may be provided to house components of lighting device 300, including LED strips 301a, 302b, and ECF strips 304a, 304b and the diffuser 305.

The dimensions of the lighting device 300 are not particularly limited and are determined by factors such as, for example, design constraints based on the space in which the lighting device is to be used, materials being used to construct various components of the lighting device, commercial availability or manufacturability of some or all of the components of the lighting device, etc. Common dimensions of such devices may include, without limiting the scope of this disclosure, 1′×1, 2′×2′, 3′×3′, 1′×4′, and 2′×4′.

The lighting device, as shown in FIG. 7B, includes 4 different types of ECFs, 304a, 304b, 304c and 304d, to generate 4 different output spectra by disposing the 4 different types of ECFs, 304a, 304b, 304c and 304d, on different LED strips within the lighting device. It will be appreciated that while the figure shows the LED strips to be of the same type (i.e., 301), different types of LEDs (i.e., having different emission spectra with different peak emission wavelength(s)) may also be used to provide specific spectra. It will also be appreciated that while 4 different ECFs are shown in FIG. 4B, more or less number of ECF types may be used to provide more or less different spectra tailored to specific applications. The different number of spectra that can be generated using such a device is limited only by space constraints and the availability of different types of ECFs and/or light sources that can generate different output spectra. Similarly, in an embodiment, ECF 304a and ECF 304c may both be configured to convert at least a portion of a spectrum emitted by corresponding LED strips 301 into a first converted spectrum with, for example, a high blue content and a CCT of 7000-15000 K and a blue content in a range from about 30% to about 70%, and ECF 304b and ECF 304d may both be configured to convert at least a portion of a spectrum emitted by LED strips 301 into a second converted spectrum with, for example, a high yellow/red content and a CCT of 2000-5000 K and a red/yellow content in a range from about 50% to about 85% (i.e., spectral power distribution of between 50 and 85% in the red/yellow region). In such an embodiment, only the LED strips 301 corresponding to ECF 304a and ECF 304c may be powered when light with high blue content is desired, while only the LED strips 301 corresponding to ECF 304b and ECF 304d are powered when light with high red/yellow content is desired.

It will be appreciated that while 4 EC blocks are shown in FIG. 5B, those of ordinary skill in the art will be able to suitably modify the luminaire for a desired application based on an understanding the concepts disclosed herein. For example, more or less number of LED strips (e.g., 2, 3, 4, 5, 6, 7, 8, 9, 10, or more) and EC blocks (e.g., 2, 3, 4, 5, 6, 7, 8, 9, 10 or more distinct EC blocks such that each of the LED strips is covered) can be used depending on the application. Likewise, the LED strips need not be arranged parallel to each other. For example, while the figures show generally square shaped back-lit luminaires, other shapes such as, rectangular, circular, ellipsoidal, hexagonal, etc., can be implemented with modifications based on an understanding of the concepts disclosed herein. Moreover, the placement of the LED strips within the shape of the lighting device is not particularly limited so long as the light emitted from the diffuser 305 into the viewing hemisphere is generally uniform. FIGS. 7C-7F show various examples of positioning of LED strips within the lighting device. For example, as shown in FIG. 7C, the LED strips can be positioned along a length (or a width) of the lighting device, with the two kinds of LED strips (or two different types of ECFs) being positioned alternately. In another example, as shown in FIG. 7D, several pairs of LED strips are positioned along a length (or a width) of the lighting device, and each pair includes two different types of LED strips (or two different types ECFs disposed on the LED strips). It will be appreciated that instead of pairs, triplets, quartets, etc. may also be used. In yet other examples, as shown in FIGS. 7E and 7F, the LED strips may be arranged diagonally or in a circular pattern so as to increase the uniformity of the light emitted by the lighting device.

It will further be appreciated that while embodiments with providing two different light spectra are disclosed herein, embodiments with more than two different light spectra, e.g., 3, 4, 5, 6, 7, 8, 9, 10, or more) are within the scope of this disclosure. Upon understanding the present disclosure, the embodiments described herein can be suitably modified to provide more than two different light spectra. Similarly, the precise composition of the light spectrum provided by the energy conversion components can be tailored by appropriately selecting the various energy conversion elements (e.g., dyes, fluorophores, phosphors, photoluminescent materials, etc.) to tailor the light spectrum for the particular plant being illuminated using the grow light. Thus, by changing the composition of the energy conversion component, the light spectrum to which the plant is being exposed can be tailored based on species or sub-species of the plant such that the plant yield is maximized.

In some embodiments, a continuous rolling sheet of energy conversion film may be positioned on the front face of the grow light (instead of the energy conversion film(s) being positioned statically on the LEDs or the front face of the grow light). Such embodiments are discussed elsewhere herein in the context of edge-lit luminaires. Those embodiments may be suitably modified to function with back-lit luminaires. As with those of the edge-lit luminaires, in such embodiments, any number of different compositions of energy conversion films can be provided. Moreover, in such embodiments, it is relatively easy to change the energy conversion films as their conversion efficiency decreases over time.

Sensor-Based Multi-Spectrum Embodiment

Referring back to FIG. 4A, in some embodiments, lighting device 200 further includes a power supply 208 which is configured to provide power to LED strips 201a, 202b. In some embodiments, lighting device 200 may be switched between a first state (e.g., high blue content), wherein power supply 208 provides power to LED strips 201a but not to LED strips 201b, and a second state (e.g., high red/yellow content), wherein power supply 208 provides power to LED strips 201b but not to LED strips 201a.

In some embodiments, lighting device 200 may be configured to gradually transition from the first state to the second state and vice versa. In some embodiments, lighting device 200 may be programmable such that lighting device 200 transitions between the two states at predetermined times which may be set by a user. For example, in an embodiment, the programming of the lighting device 200 is achieved using a microcontroller. The microcontroller, in an embodiment, may use pulse-width modulation (PWM) to output an analog voltage. The PWM signal is run through a low pass filter that is set up for a frequency that is substantially lower than that of the PWM, resulting in the square wave of the PWM to be converted to a constant voltage that is the average of the voltage from the PWM. From the low pass filter, the signal is sent through an operational amplifier to amplify the voltage. The output of the operational amplifier is then connected to the input of the LED strips 201a, 201b. The microcontroller can then be used to change the voltage provided to the LED strips 201a, 201b to obtain a smooth shift from high blue content state to a high red/yellow content state (or vice versa) over a set period at a set time.

In an embodiment, the microcontroller is connected to a network, e.g., the Internet. In such embodiments, the microcontroller can be controlled and/or programmed remotely to change the set period and the set time at which the transition between high blue content state and a high red/yellow content state is to occur, e.g., based on syncing the clock of the microcontroller with a central server, changing a set time based on local sunrise/sunset times, or signals from one or more sensor modules that sense one or more parameters relating to plant health/growth.

In an embodiment, the transition from the first state to the second state and vice versa is programmed to be triggered based on signals received from one or more sensors sensing one or more parameters (e.g., light reflectance off of plants 2, atmospheric composition, temperature, etc.). For example, in an embodiment, the lighting device 200 may additionally include one or more sensor modules, each including, for example, one or more photodiodes, a set of excitation light sources, a band pass or high pass optical filter positioned over the one or more photodiodes, an amplifier, an analog to digital converted (ADC) to read the signal strength and send it to a microcontroller, and a digital to analog (DAC) to help negate the effect of ambient light (i.e., noise) when it passes through the band pass filter. Other sensors such as, for example, a CO₂ sensor, a temperature sensor, etc. are included in some embodiments.

In such embodiments, the microcontroller is set to periodically initiate sensing of the one or more parameters. For example, the one or more parameters may be sensed every 1 minute, 5 minutes, 10 minutes, 15 minutes, 30 minutes, 60 minutes, or any other amount of time between any two of these periods. In some embodiments, the one or more parameters are sensed, for example, 1, 2, 3, 4, 5, 6, 7, 8, 9, 10 or more times per day. In such embodiments, the microcontroller is programmed to determine whether a change in spectrum and/or intensity provided to the plant is needed based on the sensed parameters, and if it is determined that a change is needed, to change power provided to appropriate LEDs within the lighting device to affect the desired change in spectrum and/or intensity.

For example, in an embodiment, at the time for sensing of the one or more light parameters, the microcontroller initiates the sensing of the one or more parameters. In an embodiment, a first reading from the one or more sensors is obtained with the excitation light in an OFF state to set a baseline against which the one or more parameters are measured. A second reading from the one or more sensors is then obtained with the excitation light in an ON state. For example, in embodiments where the one or more sensors includes a photodiode, the light emitted by the plant as a result of the excitation light is received at the photodiode and converted to a voltage signal. A normalized signal indicating the status of the plant can be obtained by subtracting the baseline signal from the second signal using either electronic or software components. In this way, the signal to noise ratio of the system can be maximized. Insofar as the ambient light (both visible and infrared components) from the grow lights can be reflected from and can stimulate optical emission from the plants, this normalization removes this light by treating it as background noise.

When plants absorb light or photons, the photonic energy can be used to either drive photosynthesis to support plant growth, or can be released as thermal energy or re-emitted as chlorophyll fluorescence. The one or more sensors can be configured to detect the energy associated with chlorophyll fluorescence, which typically peaks at 680 nm and 740 nm. Therefore, using a photodiode with high sensitivity in a range from about 660 nm to about 700 nm, e.g., from about 665 nm to about 695 nm, from about 670 nm to about 690 nm, from about 675 nm to about 685 nm, or any other range centered around about 680 nm, centered around about 670 nm, centered around about 672 nm, centered around about 674 nm, centered around about 676 nm, centered around about 678 nm, centered around about 682 nm, centered around about 684 nm, centered around about 686 nm, centered around about 688 nm, centered around about 690 nm, or in a range from about 720 nm to about 760, e.g., from about 725 nm to about 755 nm, from about 730 nm to about 750 nm, from about 735 nm to about 745 nm, or any range centered around about 740 nm, centered around about 738 nm, centered around about 736 nm, centered around about 734 nm, centered around about 732 nm, centered around about 730 nm, centered around about 742 nm, centered around about 744 nm, centered around about 746 nm, centered around about 748 nm, centered around about 750 nm, can improve the signal to noise ratio of the sensor system for higher reliability and accuracy. The voltage signal received from the photodiode is amplified and converted to a digital signal using the ADC. The digital signal from the photodiode is normalized to the baseline signal received when the excitation light is OFF. It can be appreciated that a high signal of fluorescence indicates that the plant is not utilizing light for photosynthesis, and as a result, less light may be required by the plant. As used herein, the term “about” used in conjunction with a quantity refers to a tolerance of 10% deviation from the quantity.

The microcontroller may then determine, based on the normalized signal, whether a change in state from high blue content spectrum to a high red/yellow content spectrum (or vice versa) is needed to maintain a desired plant health and/or yield.

It will be appreciated that while the embodiments describing automated change of state of the light emitted by the lighting device are discussed with respect to an edge-lit lighting device, the programming of the microcontroller can be suitably modified to function with other lighting devices, e.g., back-lit lighting devices described herein.

Plant growth can be characterized as having three (3) stages referred to as the lag stage, log stage and stationary phase. Determining which stage of growth, the plant is in is done by measuring the growth rate. The referenced sensor detects this growth rate as a function of emitted light. There are other ways of detecting the growth rate including but not limited to measuring the change in the weight of the plant, measuring change in high of the plant or density of the canopy through traditional and or computer vision methods. Insofar as plants need lights of different spectra during different stages of plant life, the systems and methods described herein provide a mechanism to change the spectrum of a grow light being used to provide light to the plant by detecting a signal from the plant.

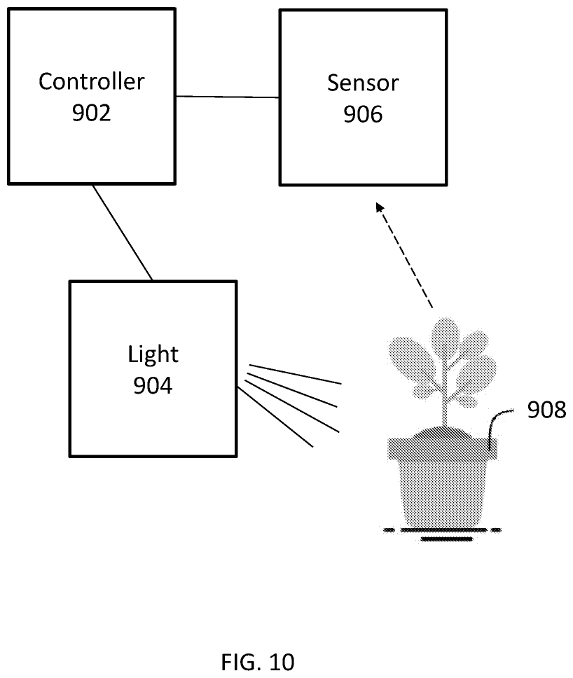

FIG. 10 illustrates a conceptual representation of the grow light control system 900, according to at least one embodiment of the disclosure. In some embodiments, the grow light control system 900 may include at least one of: a controller 902, an light 904, and a sensor 906 that, in conjunction, may be configured to control light intensity and spectral characteristics of the light emitted onto the plant 908 preferred for certain stages of the life cycle of the plant 908 and as determined by an appropriate algorithm.

The light source 904 may be configured to emit source light to the plant in the grow area. In some embodiments, the source light may have certain source light characteristics including light intensity and spectral wavelength properties (e.g., peak color components). The light source 904 may include one or more LEDs with one or more energy conversion components, e.g., as described in FIG. 4A or FIG. 7A.

The light sensor 906 may be configured to detect reflected and/or fluorescence light from the plant 908 (hereinafter referred to collectively as reflected light, unless otherwise made clear by context), for example as described herein. In some embodiments, as described herein, the light sensor 906 may include a photodiode with sensitivity peak at, e.g., a wavelength of about 740 nm. In some embodiments, the reflected light may have a reflection wavelength spectrum. The light sensor 906 may generate light sensor data representative of the reflected and fluorescence light.

The controller 902 may be configured to receive the light sensor data. The controller 902 may be configured to determine any needed modification of the source light characteristic of the source light based on the light sensor data and plant characteristic criteria. Examples of plant characteristic criteria may include plant stage characteristics of the plant 908. Examples of modifications may include modifications to light intensity and or spectral characteristics of the light 906.

In some embodiments, the plant characteristic criteria include a condition that a criterion is met when the plant 908 transitions from one stage to another. For example, the lag phase may correspond to a germination stage of a plant, the exponential phase may correspond to a vegetation stage of the plant and a stationary phase may correspond to a reproduction phase. In some embodiments, a change in growth rate (as detected by the sensor readings) is at least one indicator of a transition between plant stage. As illustrated in the graph, the plant will grow really slowly at first then increase the growth rate quite rapidly before slowing back down again. Depending on the type of plant this cycle can take anywhere from a few weeks to several months. The grow light control system described herein can detect the moment that the growth rate slows down to a point that is no longer economical for a grower to continue growing the crop.

In some embodiments, the plant characteristic criteria includes a criterion which is met, e.g., when the plant 908 transitions from a germination stage (e.g., initial baseline light intensity reading) to a vegetative stage, and wherein the controller 902 is configured to alter the light from, e.g., having a spectrum suitable for effective germination (depending on the plant) to e.g., a spectrum having an increased amount of blue light in the 440 to 470 nm.

In some embodiments, the plant characteristic criteria includes a criterion which is met, e.g., when the plant 908 transitions from a vegetative stage to a reproductive or flowering stage, and wherein the controller 902 is configured to alter the light wavelength spectrum from, e.g., having a peak in red wavelength range of 625 nm to 700 nm to, e.g., having an increased amount of light in the blue wavelength range of 440 to 470 nm.

In some embodiments, the microcontroller can detect, e.g., death and the circadian rhythm in the plants by comparing the current reading of the sensor to past sensor readings with the same plant. For example, overtime as the plant grows the readings should increase, thus, if there is no increase in the readings over a predefined (e.g., 24-hour) period, it may be safe to assume that the plant may either be dying or is not able to grow any more due to environmental constraints. In some embodiments, intra-day readings from the sensor may fluctuate within a tolerable range depending on how efficiently the plant is using light from the light source. For example, when the readings temporarily decrease during the day, the readings may indicate that the plants are using light more efficiently and the opposite when the readings increase. By comparing the readings to those taken earlier in the day, the microcontroller can determine the efficiency of the plant and whether the light intensity should be increased or decreased.

In some embodiments, the grow light control system may include an Internet of Things (IoT) (or cloud) platform (representative of the microcontroller functionality in other embodiments) with two separate systems, the sensor and the light. The sensor may be configured to transmit sensor data (e.g., readings) to the cloud and to the IoT platform may subsequently communicate to the lights to control lighting functionality. This cloud communication allows the grow light control system to be remotely monitored and changed. Cloud communication also allows for an unlimited number of lights to be controlled based on readings from the same sensor, allowing each system to be modular. Each system may connect to the cloud via the microcontroller. Advantageously, sensor data stored on a cloud platform (or other remote platforms) can be analyzed along with data relating to other factors such as, temperature, humidity, CO₂ level, etc. to optimize growth conditions that may not necessarily need modulation of the spectral content of light being provided to the plant.

In some embodiments, the processing for the readings is performed on a microcontroller of the sensor which then sends commands to the light including when the light should turn on and off. In some embodiments, there is an exception where the light keeps track of the daily light integral that it has output over the course of that day. In some embodiments, if the light is under a predefined target amount light emitted for the day, the light will adjust the light output for the last few hours that it is on to ensure that the minimum light integral for the day is met. However, extending the length of time that the light is on to meet the required light integral may not be ideal because plants grow more efficiently when receiving light in circadian rhythms. Deviating from circadian light rhythms substantially may result in stressing the plant and slowing its growth.

The microcontroller can be configured to contact the IoT platform to ensure that the internal clock for the grow light control system is properly synchronized. Synchronizing the internal clock for the grow light control system may be important because the functions of the sensor may be configured to execute at predetermined times. Synchronizing the internal clock for the grow light control system can ensure that a sensor reading will be taken within at most 1/10 of a second of when the sensor reading is intended.

Synchronizing the internal clock for the grow light control system may also ensure that there is no time drift, a common problem with the microcontrollers. In some embodiments, the sensor may be configured to synchronize the sensor's clock with that of the cloud, e.g., at 7:30 am every morning to ensure that the lights in a facility turn on each day and that the lights would turn on at the same exact intended time as necessary. Advantageously, when the sensor is properly synchronized, no master control panel may be needed to turn on the lights. For example, with the same time synchronized across all sensor system the sensors may turn on all the lights to medium output at, e.g., 7:55 am, allowing the plants to “wake up.” The sensor may then proceed take its first reading at, e.g., 8 am. From there the sensor may continue taking readings every 3 min with its last reading being taken at, e.g., 11:57 pm. At, e.g., 12:03 am the sensor may turn of all the lights allowing the plants to rest.

In some embodiments, the sensor can also detect “stress proxy” (related to stress in some capacity) of the plants by comparing the sensor reading at that time to sensors reading the sensor took previously (e.g., 24 hours ago). Without wishing to be bound by theory, the sensor readings seen by the sensor are expected to increase, if the spectrum or other environmental conditions have not changed significantly. To allow for differences in the circadian rhythm and light intensities at the time of a sensor reading, new sensor readings may be at least 98% of the reading taken 24 hours ago.

In some embodiments, the sensor reading to detect “stress proxy” may only occur once an hour or less. This can be increased if needed. If the decrease is more than 98% it may indicate that the plant is experiencing some type of “stress proxy”. In some embodiments, two repeated readings showing stress may be obtained before to deem the plant is possibly stressed to ensure that that there was no false positive. If the sensor deems that plant is stressed or dying, the sensor may communicate with the lights (e.g., through the microcontroller) be turned down to low levels slowing down all the plants systems, giving the grower more time to respond to the plant before it dies. In some embodiments, the IoT system may alert the grower that the plants are not in good health via text, email alert, or other similar communication methods.

In some embodiments, the plant may need to have been under the sensor for a predetermined period of time (e.g., 24 hours) to enable a baseline to be established for the plant before the sensor is able to determine if the plant is stressed. In some embodiments, the plant can be stressed during this 24-hour timeframe, if the “stress proxy” gets worse, the system may detect this and alert the grower but if the stress goes away the sensor will be able to continue functioning normally.

In some embodiments, the sensor may also assess the efficacy of the growing system by capturing response data during the normal circadian cycles of the plant and comparing changes with previous cycles. If the sensor deems the plants are not efficiently using the light available from the grow light, a control system may adjust the intensity of the grow light so as to produce an optimized growth response. For example, the control system may reduce the grow light intensity by a predetermined value (e.g., 8%, or 10%, 15%, 18%, 20%, 25%, 30%, etc.) of the lights standard value until the lights are running at a lower value (e.g., at 90%, 85%, 80%, 75%, 70%, 60%, 65%, 50%, 55%, 40%, 45%, 30%, etc. of the standard value). Conversely, the grow light may incrementally increase by a predetermined value, (e.g., 8%, or 10%, 15%, 18%, 20%, 25%, 30%, etc.) of its standard value each time until the light is at a higher value (e.g., 110%, 115%, 120%, 125%, 130%, 140%, 150%, 160%, 170%, 175%, 180%, 190%, 200%, etc. of its standard value). After a light intensity change, the system may include lockout period during which the grow light intensity cannot be changed to condition the plants to the new light intensity.

In some embodiments, the spectrum of light emitted by the grow light may be changed. For example, based on an analysis of the data received from the growth control sensor, the system may identify that the plant has transitioned to a different growth stage, and that the optimal spectrum of light needed for the plant needs to be changed. In such instances, the system may cause the grow light to change the spectrum of light output, e.g., from high blue content to high red/yellow content.

Thus, if it is determined a change in state of the light emitted by the lighting device is needed, the microcontroller communicates with the power supply to appropriately change the state of light as described elsewhere herein.

It will be appreciated that while the embodiments describing automated change of state of the light emitted by the lighting device are discussed with respect to an edge-lit LED lighting device, the programming of the microcontroller can be suitably modified to function with other lighting devices used for similar purposes.

In an aspect of the present disclosure, a growth control sensor module can be used as a standalone growth sensor module with any lighting system to generate data relating to plant health. Plant health can be determined by assessment of plant photosynthesis and respiration rates, such as may be obtained by measurement of chlorophyll fluorescence at long red or near infrared wavelengths. A sensor that can remotely measure plant photosynthetic rate requires an exciting radiation source that can stimulate chlorophyll fluorescence and a photodetector capable of capturing light reflected and emitted from the plant. A useful source of excitation radiation will have an emission in the range 400-500 nm, and preferably in the range 440-470 nm. To best discriminate plant fluorescence from other sources of light, it is preferred that the detector is configured to capture only light at far red and infrared wavelengths, and in particular in the range of 660-760 nm.

Finally, it is important that the intensity of the light be sufficiently greater than that coming from the grow lights, but not so intense as to cause photosynthetic pigment saturation or damage to the plant. As such, the excitation light should be in the range from about 400 μmol/m²s to about 8000 μmol/m²s, and preferably in the range from about 400 to about 4000 μmol/m²s, particularly in the range from about 400 μmol/m²s to about 800 μmol/m²s, e.g., about 400 μmol/m²s, about 425 μmol/m²s, about 450 μmol/m²s, about 500 μmol/m²s, about 525 μmol/m²s, about 550 μmol/m²s, about 575 μmol/m²s, about 600 μmol/m²s, about 625 μmol/m²s, about 650 μmol/m²s, about 675 μmol/m²s, about 700 μmol/m²s, about 725 μmol/m²s, about 750 μmol/m²s, about 775 μmol/m²s, about 800 μmol/m²s or any value between any two of these values. In some embodiments, depending on the particular plant species and variety, the intensity of the excitation light may be greater than about 800 μmol/m²s, e.g., about 900 μmol/m²s, about 1000 μmol/m²s, about 1100 μmol/m²s, about 1500 μmol/m²s, about 2000 μmol/m²s, about 2500 μmol/m²s, about 3000 μmol/m²s, or any other value between any two of these values. Plant status can be determined by tracking the fluorescence signal over time, with decreases in signal indicating increased photosynthesis and increases in fluorescence indicating less use of light for photosynthetic processes.

In some embodiments, the growth control sensor module may include an excitation light source, such as one or more LEDs. Other sources such as incandescent or flash lamps could also be used. The excitation light may provide brief pulses of light, e.g., of around 1 second duration, that are sufficiently intense to excite fluorescence of the chlorophyll in the plants and can be detected by a photodetector.

Detection of fluorescence light from plants requires separation of the infrared fluorescence signal from other ambient light. In some embodiments, the fluorescence signal stimulated by the excitation light is sufficient to assess plant status without any additional processing to increase signal to noise. In systems that generate a low fluorescence signal compared to that from the ambient light, this can be accomplished by generating the fluorescence on a carrier signal that can be extracted by lock-in amplification. Alternatively, if the intensity of the excitation light is sufficiently high, then the fluorescence signal may be extracted by subtraction of a baseline or background ambient signal.

In some embodiments that utilize one or more LEDs as the excitation light source, the wavelength band of the excitation light may be chosen for both good LED conversion efficiency, and good spectral overlap between the LED emission and the excitation spectrum of the fluorescence response from the plant and may be substantially in the range from 440 to 495 nm. In some embodiments, commercially available LEDs frequently classified as “Royal Blue” in color may be used. In some embodiments, secondary optical lenses, such as, e.g., those made by Carclo Technical Plastics, may be used to concentrate and re-direct the disperse LED light from the LEDs toward the direction of the plants being monitored, minimizing wasted light, and stray excitation of adjacent plants, and to further increase the desired fluorescence signal.

In some embodiments, a lock-in amplifier may be used to filter out ambient noise such as sunlight when extracting the photodiode signal from a sensor reading. Foregoing using the lock-in amplifier may be good for environments in which there is no sunlight or chaotic artificial light allowing for reduced cost, power consumption, and size, but increased sensitivity, reliability, and accuracy. The lock-in amplifier may be utilized in green houses that use sunlight. The lock-in amplifier may be configured to operate in conjunction with a photodiode to detect light at about 740 nm. In some embodiments, the analysis light may pulsed on and off at a certain frequency, e.g., 200 times per second (200 Hz).

In some embodiments, the sensor signal may pass through an instrumentation amplifier such as, e.g., an LT1920 instrumentation amplifier, to amplify the signal, e.g., by a factor of about 100. From the amplifier, the signal may then be transmitted to a low pass filter. The low pass filter may remove all signals that exceed a predetermined frequency (e.g., 500 Hz in frequency). In some embodiments, the signal from the low pass filter may be amplified again, e.g., by a factor of about 10, by an operational amplifier (e.g., the OPA-180 (a zero-drift OP-AMP)) to compensate for the signal strength loss that occurs when the signal passes through the low pass filter.

The signal may then go to an analog to digital converter chip. In some embodiments, this converter may take readings at high rates to allow a microcontroller to function as a lock-in amplifier. In some embodiments, this chip may then send the reading to a microcontroller having an on-board communication capability such as, for example, capability of utilizing an Internet of Things (IoT) communication protocol. For convenience of description, such microcontrollers are collectively referred to herein as IoT compatible microcontrollers, even though they may use other types communication protocols. In some embodiments, a Particle Photon microcontroller may be used. The IoT compatible microcontroller may connect to, e.g., a public cloud network for data storage and control how often readings are taken. The system may also account for ambient noise in the environment by taking a reading at a predetermined interval (e.g., ½ a second) before the analysis light is turned on. The system may then proceed to take the readings with the analysis light turned ON and then find the difference between the consecutive readings.

In some embodiments, the use of a lock-in amplifier can be avoided. In some embodiments, the system may use a photodiode to absorb only light at about 740 nm. The analysis light may be turned ON for readings. The signal may then pass through an instrumentation amplifier. From the instrumentation amplifier the signal may then go to the low pass filter. The system may be configured to restrict signals higher than, e.g., 100 Hz from passing through. From the low pass filter, the signal may then proceed to the zero-drift OP-AMP the OPA-180 which may amplify the signal by a predetermined factor (e.g., between 10-15 times). The signal may then be passed to an analog to digital converter. The analog to digital converter may then pass the signal onto a microcontroller such as the Particle Photon.

In some embodiments, the signal may be sent to an analog-to-digital converter (e.g., LTC2451). From the analog-to-digital converter, the digital signal can be transmitted for a certain distance, e.g., 15 ft., over a cable allowing for the microcontroller to be on the power supply or for the sensor module to plug directly into the grow light.

In some embodiments, the system may also utilize a switch that is connected to the microcontroller that may control the resistance between the photodiode and the ground. By changing the resistance, in some embodiments, the sensor systems can operate in ambient light ranging from complete darkness to up to 1500 micromoles/m²s, such as the illumination typically provided in greenhouses with artificial lighting. In some embodiments, a system with a lock-in amplifier system can operate in environments up to, e.g., 2500 micromoles/m²s. The lock-in amplifier system may use the same method of taking a reading without the lights to account for ambient light.

In some embodiments, the system may be capable of measuring both fluorescence light emitted from the plant and some wavelength in the green spectrum, e.g., about 500 nm, to allow for estimation of reflectance of the plant.

In some embodiments, the sensor system may include two Printed Circuit Boards (PCBs) to accommodate 1) LED driver, power supply and microcontroller, 2) excitation LEDs and other key sensor components including photodiode and analog to digital converters. Each sensor may require its own microcontroller. In some embodiments, only a single power supply and control unit board using a single microcontroller may be needed. In some embodiments, 8 or more sensor modules can be plugged into a control unit with each module having up to a cable of a certain length, e.g., 15 ft. In some embodiments the LED driver may be located on the sensor module.

In some embodiments, the sensor system and lights may require a multitenant cloud network in order to store sensor data and communicate sensor systems. In some embodiments, the sensor system and lights may include a web or app-based user interface so that users can change settings on the sensor such as how often it takes readings or how bright the grow lights will be.

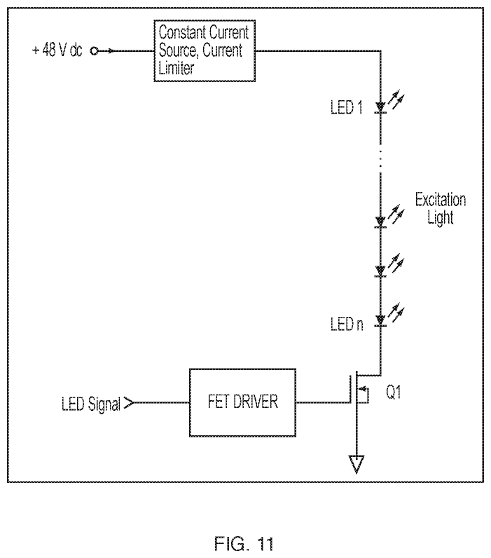

FIG. 11 shows a schematic circuit diagram for an excitation light source. In some embodiments, the excitation light source may be powered by a remote connection with a communications module which provides voltage sufficient to support the required forward voltage of the LEDs (1 thru n) along with any distribution and circuitry losses. In such embodiments, the communication module may supply 48 V DC to a current limiting device such as, for example, a LM317 positive voltage regulator, which provides a maximum current around 700 mA to 12 series connected LEDs as shown in FIG. 11. The constant current source and current limiter provides a maximum current to the LEDs which is independent of the LED series forward voltages and therefore, provides control over the power dissipated by the LEDs and the radiant light power of the excitation light. In some embodiments, the LEDs may be pulsed, e.g., approximately 1 second duration pulses, at programmable intervals ranging from, e.g., 2 minutes to several hours or more. In the embodiment shown in FIG. 1, a transistor Q1 operates as a switch to ground to complete the LED series circuit and provides the pulsed current to the LEDs. In some embodiments, a FET driver integrated circuit (IC) is used to translate the lower power digital signal (labeled in FIG. 11 as LED signal) to sufficiently drive the gate input of Q1.

In some embodiments, the excitation light source circuit can be implemented on a fiberglass PCB that may include thermal vias to help remove heat away from the LEDs where the metal core board is more conductive to heat and distributes heat without thermal vias. A heat sink can further be added as required to control LED junction temperature, in some embodiments.

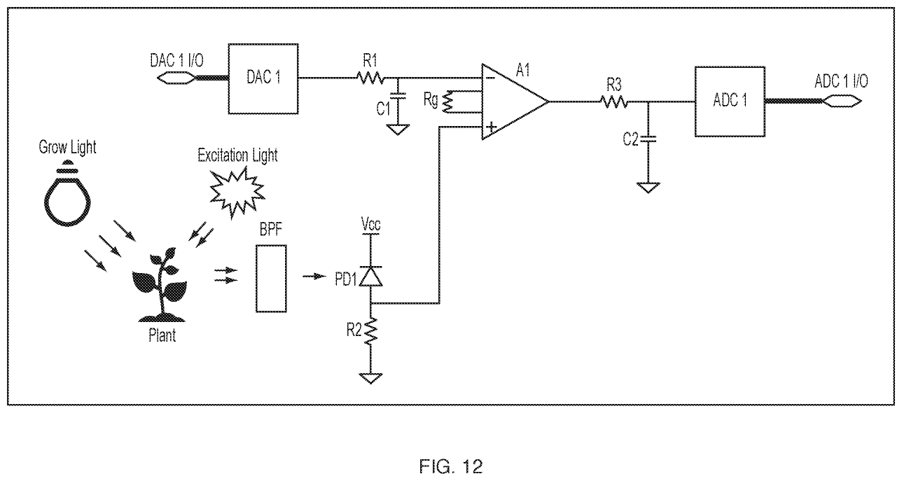

In some embodiments, the growth control sensor may further include a photodetector. FIG. 12 shows the photodetector and its related schematic elements, as well as a grow light, a plant, and excitation source and a wavelength selection element. The grow light and the excitation light sources provide radiant light onto the plant. Reflected and fluorescence light are re-radiated from the plant. This combined re-radiated light is incident on a photodetector module.

In some embodiments, the photodetector module includes one or more photodetectors and at least one selective optical element to provide wavelength discrimination. The one or more photodetectors may be selected from commercially available silicon photodiodes, PIN diodes, APD's, CCDs, PMTs, etc.

Referring back to FIG. 12, in an embodiment, the spectrally filtered light is incident onto a photodiode PD1. The photodiode PD1 may be reverse biased by the supply voltage Vcc, e.g., 5 V DC. The photodiode PD1 responds to the filtered incident light by generating a leakage current proportional to the light flux through a resistor R2, which can have a resistance of, e.g., in the range from about 50 kohms to about 300 kohms, from about 50 kohms to about 500 kohms, from about 50 kohms to about 1 Mohms, from about 50 kohms to about 10 Mohms, or even larger resistance. The resistor R2 converts the photodiode current into a measurable voltage.

The photodetector module receives light from the plant including ambient background light. In order to discriminate the fluorescence light from the plant from other light, the photodetector module, in some embodiment, includes a selective optical element. The selective optical element may be placed in close proximity to the photodiode. Stray light, which does not pass through the selective optical element should preferably be shielded from reaching the detector as much as possible. This may be achieved by either fixing the selective optical element over the photodetector within a metal package header typically used for through-hole mounting photodiodes such as, e.g., package types TO-46 or TO-18. More economical and the preferred alternative embodiments may include a pre-packaged surface mounted photodiode and affixing the selective optical element directly over the photodiode, the element being held in place by either a plastic housing mounted on the board or as part of the sensor housing itself.

In some embodiments, the selective optical element may be a dichroic band pass filter (BPF) with a pass band centered, e.g., at about 740 nm and a full width half maximum width of about 10 nm. This element serves to both pass the chlorophyll fluorescence signal and reject out-of-band reflected and ambient light wavelengths. Alternative constructions could also be a combination of high pass and low pass filters, or a spectral grating, or a MEMS (Micro-Electromechanical System) configured to perform the wavelength selection function or to select a spectral band exhibiting chlorophyll fluorescence. In some embodiments, commercially available similar detector and wavelength discrimination devices, sometimes called “spectrometer on a chip”, could also be used. These can fall into three categories; pre-packaged diode arrays with various optical filters mounted over them or integrated onto an array of photodetector elements, those consisting of a spectral grating and one or more photosensitive elements such as a photodiode, a CCD array or a photodiode array, and those consisting of MEM mirrors which are positioned and programmed to achieve wavelength discrimination using additive and subtractive interference by use of variable and controlled pathlengths.

In some embodiments, the photodetector module may include additional optical elements providing optical magnification or field of view control for the photodiode to increase or decrease the operational distance between the receiver module and the plant. Examples of photodetectors include, but are not limited to, silicon photodiodes, PIN diodes, avalanche photodiodes (APDs), charge coupled devices (CCDs), photomultiplier tubes (PMTs), etc. In addition, the photodetector may also include a camera or a 2-dimensional (2D) imaging device such as a CCD or a CMOS image chip in combination with an imaging lens. In such cases, the imaging system may include an optical filter to discriminate IR light from visible wavelengths. Cameras that are often used in horticulture systems to monitor plant status can be used as sensors with the use of such an optical filter.

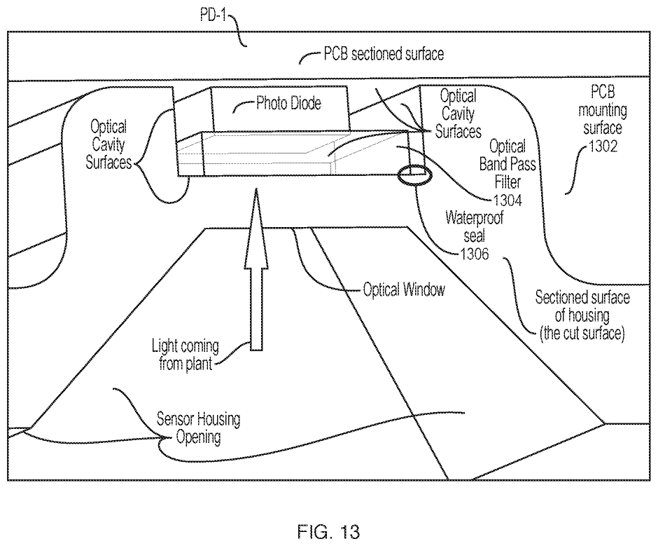

For purposes of example, FIG. 13 shows a cross-sectional view of an mechanical embodiment of the photo-diode portion of the growth control sensor. A surface mount photodiode PD1 is soldered to the PCB mounting surface 1302. Above the photodiode's photosensitive surface an optical band pass filter 1304 is held in place by the sensor module housing and sealed along its edges with a water-proof seal 1306, for example a gasket, or a polymer adhesive. The PCB and sensor module housing form a cavity in which the photodiode sits. The surfaces of this cavity may be coated with a light absorbing material to reduce stray and un-filtered light encroachment from directions other than the intended optical surface which is contained in the optical window of the housing. The sensor housing opening surfaces can be coated with; reflecting, absorbing, or something in-between materials in order to change the directionality and sensitivity of the photodiode. Any additional optical elements such as a lens could be affixed within the sensor housing opening.

Referring back to FIG. 12, the photodiode PD1 current creates a voltage across resistor R1 which is applied to the + (plus) amplifier A1 input. Resistor R1 converts the diode current to a voltage and so the value of resistor R1 contributes to the photodetector+amplifier Al photo detector system voltage gain. Amplifier A1 may be an instrumentation amplifier such as, e.g., Analog Devices AD8226. The gain of the instrumentation amplifier A1 may be set by voltage gain resistor Rg with a voltage gain of approximately 100×. The amplifier A1 is configured to subtract the voltage applied to the − (minus) amplifier input from the + (plus) input and amplify the difference by approximately its programmed gain (100×). Alternatively, a one or more ordinary operational amplifiers (“Op-Amps”) could be used to provide both amplification and subtraction functions in a similar manner.

Resistor R1 and capacitor C1 perform signal conditioning in the form of a low pass filter for the DAC 1 (Digital to Analog Converter) voltage to reduce high frequency residual noise from the DAC output. In some embodiments, the DAC1 may be a microchip such as, e.g., MCP4728 with 4 outputs of 12 bit resolution.

Likewise, resistor R3 and capacitor C2 perform signal conditioning in the form of a low pass filter for the output signal from amplifier A1. This filter suppresses undesirable high frequency components of the ambient light detected by photo-diode PD1, and wide band circuit noise generated by the photodetector and amplifier circuitry, and stray electrical pick signals up such as from radio transmission, fan motors, power supplies etc.

Because there is residual ambient and reflected light from the plant and its surroundings which are in the range of the fluorescence wavelengths, they will pass through the band pass filter BPF along with the fluorescence portion of the light detected by photodiode PD1. Therefore, the detected light may be corrupted and even overwhelmed by an ambient background signal. The useful fluorescence part of the signal detected by photodiode PD1 needs to be extracted from this ambient background noise consisting of both a relatively constant or slow DC components and higher frequency components originating from various sources.

While embodiments described herein utilize an electric circuit to perform the subtraction for extracting the fluorescence signal and improving the signal to noise ratio, it will be appreciated that the subtraction may be performed without the electric circuit described herein. For example, the subtraction may be formed by the microcontroller in some embodiments. Likewise, the subtraction may be performed by a software program before transmitting the data to the cloud for storage and/or further analysis.

In a method of use, in one embodiment, an ambient system illumination with no excitation light is detected using a photodiode or other similar photodetector. The ambient detected signal is then used as an offset signal. The excitation light is then turned on for a duration, e.g., in a range from 0.1 s to 10 s, and the fluorescence light generated is detected with the photodetector. The offset signal is subtracted from the detected fluorescence signal and the difference is amplified. The amplified signal is filtered through a low-pass filter and digitized to generate a processed digital fluorescence signal.

The method for detecting the fluorescence-excitation described herein is simply in that it consists of an analog subtraction, and robust in that it tracks changes in the ambient conditions as well as relative motion of the sensor and plant by self-calibration before taking fluorescence readings. By adjusting the photo-diode gain, the intensity of the excitation light, and sensor field of view, the system can be configured to make accurate fluorescence readings from relatively small distances ranging from about 4 inches to about twenty feet away. This can provide workable solutions for various grow room requirements. Advantageously, the measurement cycle does not require interruption of the grow light or that the measurement be made in a darkened room. This is because both reflected and fluorescence signals resulting from ambient light are measured and effectively canceled during the process described, providing increased signal-to-noise ratio beyond that provided by the raw optical signal detected. The signal-to-noise ratio may be greater than 1.5, greater than 2, greater than 3, greater than 4, greater than 5, or even larger.

In an exemplary method using the system described in Example 1, while the excitation light is off, the baseline ambient optical signal level is detected by the detector after passing through a band pass filter to isolate a spectral band associated with the desired plant fluorescence, typically in the range from 650 nm to 780 nm, e.g., in a range from about 660 nm to about 760 nm, from about 665 nm to about 755 nm, from about 670 nm to about 750 nm, from about 675 nm to about 745 nm, or any range centered around about 680 nm or any range centered around about 740 nm, and the resulting signal digitized by an Analog to Digital Converter, ADC 1. The digital value is processed by software which may generate a digital offset signal which may be fed back into the Digital to Analog Converter DAC1 through signal DAC1 I/O. The software is capable of calibrating or zeroing of the amplifier A1 so that the steady state background ambient signal at the (+) input is matched at the (−) input, resulting in a zero or near zero signal at its output after input subtraction and amplification by amplifier A1. This process of calibration or zeroing may be repeated immediately before every excitation light cycle which is used to measure plant fluorescence.

Continuing the exemplary method, one of the other four DAC outputs may be used to produce the LED Signal pulse such as described in FIG. 11. The excitation light source is turned on in a steady state condition with a duration in the range of about one second. The excited-fluorescence signal from the plant is very small in comparison to the ambient reflected or ambient fluorescence light generated by grow lights. The received light is passed through an optical band-pass filter (BPF). Because the amplifier A1 (−) input has been calibrated to the most recent ambient level, amplifier A1 amplifies the difference between the ambient signal level or offset and the ambient signal level plus the plant fluorescence at the amplifier A1 (+) input by the gain setting of amplifier A1. High frequency components of the difference signal are filtered by resistor R3 and capacitor C2 as described elsewhere herein and the result is digitized by ADC1.

In an embodiment, the Analog to Digital Converter ADC 1 may be a Texas Instruments ADS1015 12 bit converter chip, but other converters or methods of digitization can be used. The excited—fluorescence signal with the ambient background subtracted is converted into data which can be processed further.

While embodiments described herein include a subtraction operation in the analog domain, it is also foreseeable that a system with sufficient dynamic range could perform ambient subtraction in the digital domain, meaning subtraction after the analog to digital converter. Any required signal conditioning like low pass filtering could also be performed in software program, or a DSP (Digital Signal Processor) chip.

Advantageously, because many microprocessors include both ADC and DAC functions built-in, the microprocessors themselves can replace the ADC and DAC functions in addition to providing I2C, SPI or other communications methods between the growth control sensor modules and the communications module, or to other sensor modules. This could be achieved for the same or less cost than providing those functions externally, resulting in potentially a more compact circuit and even more economical solution. Some microprocessors may also include one or more Op-Amps which could further consolidate the system design of the sensor system. Adding such microprocessors may be desirable for commercial production of sensor modules where minimizing component cost is advantageous.

In an embodiment, both DAC1 and ADC1 in the receiver module have a serial communications port and protocol referred to as I2C (Inter-Integrated Circuit). This allows multiple DAC and ADC chips in multiple receiver modules to be connected into a network through a wiring scheme commonly referred to as a daisy chain. Such an arrangement allows each receiver module to both send and receive digital data and control pulses with a master control device located in the communication module. Other commercially available data protocols are also suitable, such as SPI (Serial Peripheral Interface) as well as custom protocols.

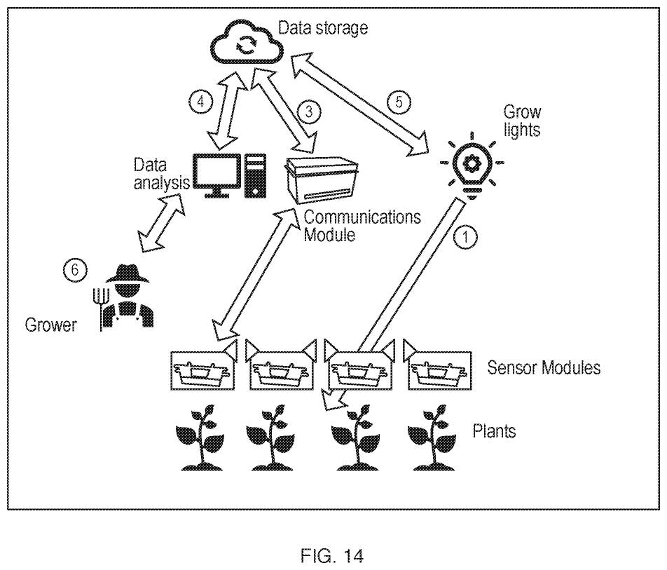

In some embodiments, each growth control sensor module may include a communication as shown in FIG. 14. In an embodiment, the power and communications and control are provided through a connector, e.g., a 6-pin connector which provides both power and digital communications and control. One pin may carry the high voltage need to power the LEDs, e.g., 48 V DC. In an embodiment, the 48 V may be used to produce local sources of 12 V DC, and 5 V DC using common voltage regulator IC's as required by the embodiment circuitry, and a constant current source for powering the excitation LEDs. One pin may carry 3.3 V also required by embodiment circuitry. Two pins carry the I2C SDA and SCL signals, and one pin carries a chip select signal. One pin carries ground.

In some embodiments, the communication module includes 2 power supplies. One of the power supplies may be located on a PCB, and the second may be located off the PCB. Both power supplies convert incoming AC voltage ranging from 100-240 V into lower DC voltage. In an embodiment, the onboard power supply may output 5 V with a max current of 2 A. This power supply may be used, e.g., to power the microcontroller on the communications module. In some embodiments, the off-board converter may supply 48 V DC at a current of up to 3 A. This power may be sent to each of the sensor modules along a bus where it is then converted down further for use of each of the systems. In some embodiments, before the AC enters any of the power supplies it may first be passed through a fuse and then a switch for added safety. The switch may be mounted on the outside of the box that encloses the boards and other circuitry, enabling the user to turn off power to the system.

The description that follows uses a Particle Photon microprocessor line; however, any microprocessor with an internet connection and I²C capabilities could be used. The Particle Photon microprocessor line is advantageous because of its integrated antenna and pre-exiting cloud infrastructure. This greatly reduce the resources needed for moving data into a cloud network. In addition, the newest version of the particle devices enables the use of one board design for all connection options. Advantageously, such architecture enables the systems to be ordered with the connection option that best suits a particular user's preferences and the environment that the sensor system will be used in. The options available for data connectivity may include, e.g., WiFi, Bluetooth, 3G cellular, and 4G cellular. Additionally, it is possible to switch from one form of connection to another by merely powering off the system, having the previous microcontroller unplugged from its headers and then plugging-in a new microcontroller.

In an embodiment, the photo-detector module of the growth control sensor module communicates with the communication modules over I²C. The I²C enables the ADC and the DAC located on each sensor module to send and receive commands from the microcontroller located on the communication module. Information sent over such a bus may be used for, e.g., turning on the excitation light for a specific growth control module, obtaining data for calibration, and obtaining the actual fluorescence data, etc.

In some embodiments, data may be published from the communication module to Particle servers through an applicable communication protocol such as, for example, Wi-Fi, 3G Cellular, 4G Cellular, or Bluetooth. The choice of communication method to the Particle servers may not change the formatting of the data or messages. In some embodiments, the Particle servers store data messages and device status messages on a temporary basis. In such embodiments, permanent storage of sensor data may be accomplished by exporting messages to an external service such as, for example, a local database, or any of the commercially available cloud platforms over, e.g., the Internet. Data processing may be performed both at the device level and the database level depending on the particular application for which the growth control sensor is being deployed.

In general, when plants absorb light, the photonic energy can be used to either drive photosynthesis to support growth or be released as heat or chlorophyll fluorescence. Photosynthesis and chlorophyll fluorescence are competing pathways for photo energy relaxation after absorption. The growth control sensor described herein detects the intensity of chlorophyll fluorescence. With appropriate analysis of current data combined with history data, the sensor readings can reflect plant growth rates associated with photosynthesis, and stress indicators under certain environment conditions including light intensity, light spectral content, temperature, humidity, CO₂ level, etc.

For example, in a typical case, within a 24-hour period, when the readings are relatively low (chlorophyll fluorescence is weak), the plant could be efficiently using photon energy provided by the grow light and actively undergoing photosynthesis. When the readings are relatively high, the plant may be under stress and/or not using light efficiently for photosynthesis. Over a longer period of time, however, a steady increase of the readings may indicate the growth of the plant (e.g. larger leaf area). Thus, for accurately determining how efficiently the plant is using photonic energy, historical data may also be considered in addition to the current data.

In some embodiments, a dimming module for a grow light described herein (e.g., with reference to FIGS. 4A, 7A, etc.) can be integrated into the growth control sensor module to regulate grow light intensity based on sensor readings, such that the plants only receive as much light as needed. The dimming module is configured to automatically modulate the light intensity in response to the detection of a stress indicator. When modulating the light intensity, the dimming module may consider slow down photosynthesis so as to reduce the rate of damage that may be occurring to the plant until a grower is able to rectify the situation. In an embodiment, the dimming module may use a self-learning algorithm which may increase in accuracy as the database of sensor readings and potential mitigating factors grows.

In addition to light intensity, another aspect of grow light is the spectral content or spectral power distribution of the light being provided to the plants. For example, for strawberry and tomatoes, optimal spectral power distribution is considered to be 16% blue centered at 450 nm, 24% centered at 530 nm, and 50% between 625 nm and 700 nm, and centered at 660 nm. Additionally, about 10% of light output to be above 700 nm is also desirable.

In another example, some species of cannabis require 18% blue centered at 450 nm, 28% centered at 530 nm, and 46% between 625 nm, and 700 nm centered at 660 nm. It has also been observed that, higher blue to red ratios promote shorter stems and bigger leaves (vegetation), while lower blue to red ratios promotes budding (flowering).\

Accordingly, in some embodiments, the overall spectral content of a grow light can be regulated by a dimming module for each spectral channel. By incrementally adjusting deviation from an above-mentioned predetermined baseline, and relating the outcome to data from the growth control sensor module, the grow light's optimal spectral content for a given plant variety can be determined in almost real time.

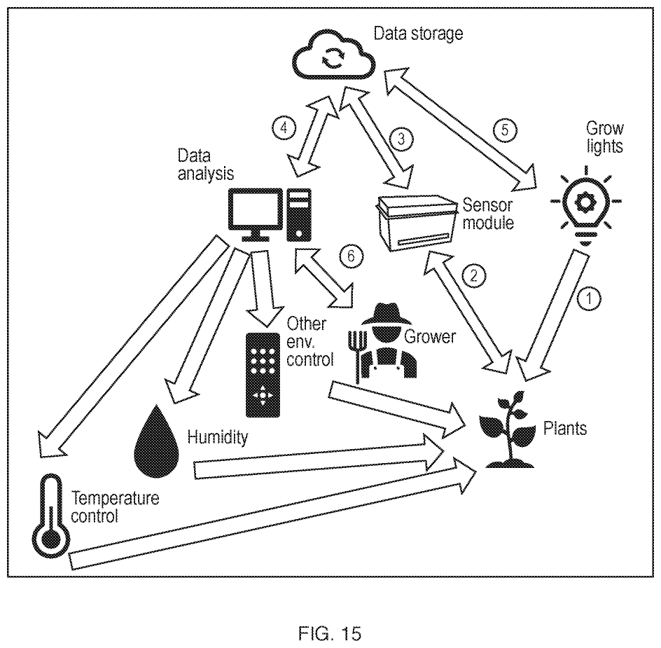

FIG. 15 shows a block diagram of interaction between various modules of the lighting system described herein, in accordance with an embodiment of the present disclosure. Grow light (1) provides energy for plant growth. The growth control sensor (2) detects a plant response. The plant response data is stored securely on a cloud platform (3). The control module (4) analyzes the data (over a period of time) to develop an algorithm for optimal growth conditions and provide insight of plant growth to the grower (6) who reviews the data and may create a custom recipe. Meanwhile, the dimming module (5) may regulate light output based on feedback from interface module to optimize energy efficiency and mitigate damage to the plant while the grower responds with an appropriate recipe.

By way of another example, and without wishing to be bound by theory, photosynthesis has two components—photons to glucose (CO₂ to O₂, and carbon is fixed as glucose), and Photorespiration (protein enzyme ribulose-1,5-bisphosphate carboxylase/oxygenase (RuBisCo) captures O₂ instead of CO₂ and partially recovers through the respiration cycle). If stromata pores do not open to let CO₂ in because of low humidity, O₂ builds up inside leaf and the plant responds by increasing the respiration cycle in which RuBisCo captures oxygen. Factors impacting pore opening are low humidity and high temperature. The growth control sensor module can detect a drop in photosynthesis rate by tracking the chlorophyll fluorescence and, advantageously, correlate it to temperature and humidity data.

Thus, by tracking plant status and health, proxy stress, growth stage, and harvest indications, the growth control sensor enables real-time monitoring of plant growth rate, plant stress indicators, and, with appropriate calibration, dry/fresh weight and leaf area of the plants, making it possible to use algorithms to optimize environment conditions for plant growth, and even predict plant yields and best harvest timing strategy.

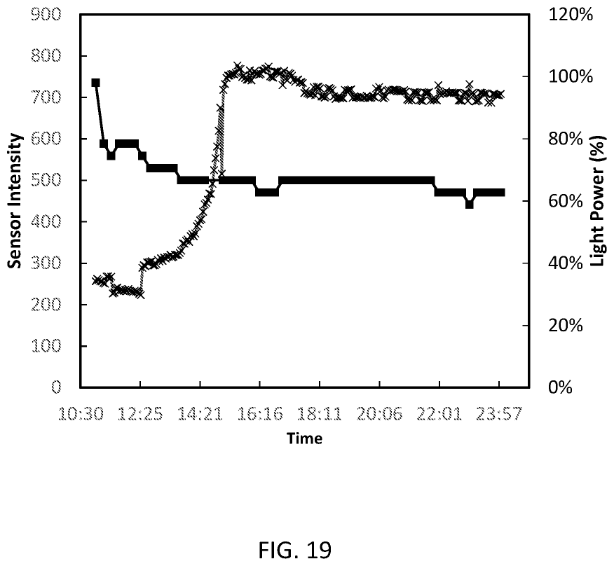

Additionally, the growth control sensor described herein may be used to regulate light intensity using a dimmable grow light where the current delivered to the grow light is based on sensor readings, such that the plants only receive as much light as needed. For example, if a stress indicator is detected, light intensity will be automatically reduced to slow down photosynthesis, thereby slowing down damage that is occurring to the plant until the grower is able to rectify the situation. In another example, increasing sensor reading (“sensor intensity” as indicated by the “X” markers in FIG. 19) within a few hours may suggest the plant's inability to use 100% of the lighting received, so the sensor system may send a command to the grow light's dimmer to cuts back on the light intensity. Compared to a light at constant 100% intensity, the average light intensity over this period is 68%. Thus, advantageously, this type of light reduction may be beneficial for both the plant itself and may result in energy savings.

Manually Switchable Lighting

In some situations, it may be desirable to convert an existing light source, e.g., a light source with high blue content into a light source that can provide light with, e.g., a high red/yellow content. For example, if an establishment already has a lighting design with high blue content lights, it may be financially prudent to convert the existing high blue content lights to lights with high red/yellow content when desired, and back to the high blue content light when the high red/yellow content light is not needed. In such situations, a suitable energy conversion block (e.g., an energy conversion film, or EC film) may be placed in front of the high blue content light source to generate light with high red/yellow content.

In an embodiment, the housing for the high blue content light is fitted with frame having a slot for sliding an appropriate EC film in or out of the frame such that the EC film placed in front of the high blue content light (i.e., between the light and the grow area). This mechanism of sliding the EC film into a predefined slot to enable conversion of light spectrum of an existing light source may also be accomplished using a motorized assembly whereby by a roll of EC film with suitable composition may be unrolled or retracted using a motorized roller to pass through the slot.

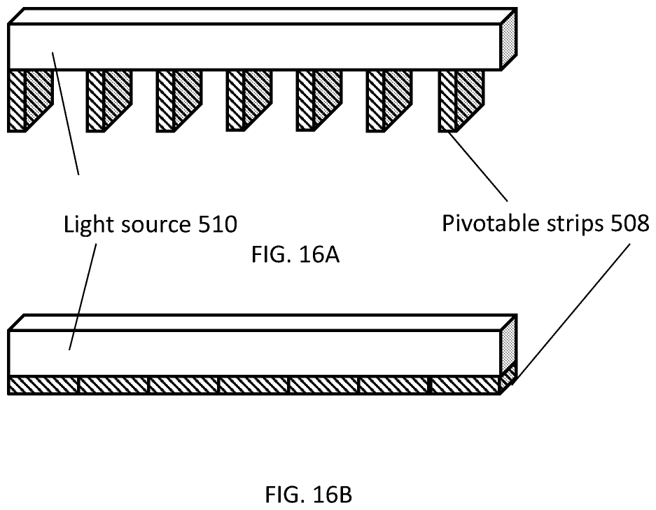

In an embodiment, the EC film may be mounted on a transparent substrate such as an acrylic sheet and formed into strips which can be pivotably attached to the light source. As shown in FIG. 16A, when the EC strips 508 are perpendicular to the existing high blue content light source 510, the light from the light source does not pass through the EC film, and thus reaches the grow area unaltered. On the other hand, when the EC strips 508 are turned (i.e., pivoted) to be parallel to the light source 510 source, i.e., as shown in FIG. 16B, each of the EC strips 508 covers a portion of the light emitting surface of the light source 510. The light emitted by the light source thus, passes through the EC strip 508 before reaching the grow area. In other words, the spectrum of the light emitted by the light source 510 is altered by the EC strip 508 before reaching the grow area. The grow area, therefore, receives light based on the EC strip selected. For example, when the existing light is a high blue content light, the EC strip 508 may be selected to have a composition that results in a high red/yellow content light. In such embodiments, the EC strip 508 can be pivoted from the perpendicular position shown in FIG. 16A to the parallel position shown in FIG. 16B when, e.g., the plant in the grow area transitions from vegetation state to flowering state. The pivoting action may be provided manually, e.g., using a mechanism, for example, similar to window blinds or a pivoting flange, or using a motorized assembly which can pivot the individual EC strips 508.

It will be appreciated that while a sliding assembly and a pivotable assembly are described herein for manual insertion or removal of the energy conversion film over an existing light source, other suitable mechanisms are contemplated within the scope of the present disclosure.

In various embodiments, the existing light source 510 may be, for example, an edge-lit luminaire, a back-lit luminaire, an incandescent light source, a compact fluorescent light source, an LED light source, or any other light source that has at least a portion of its emission spectrum in the range of 400-460 nm.

Alternate Lighting Systems

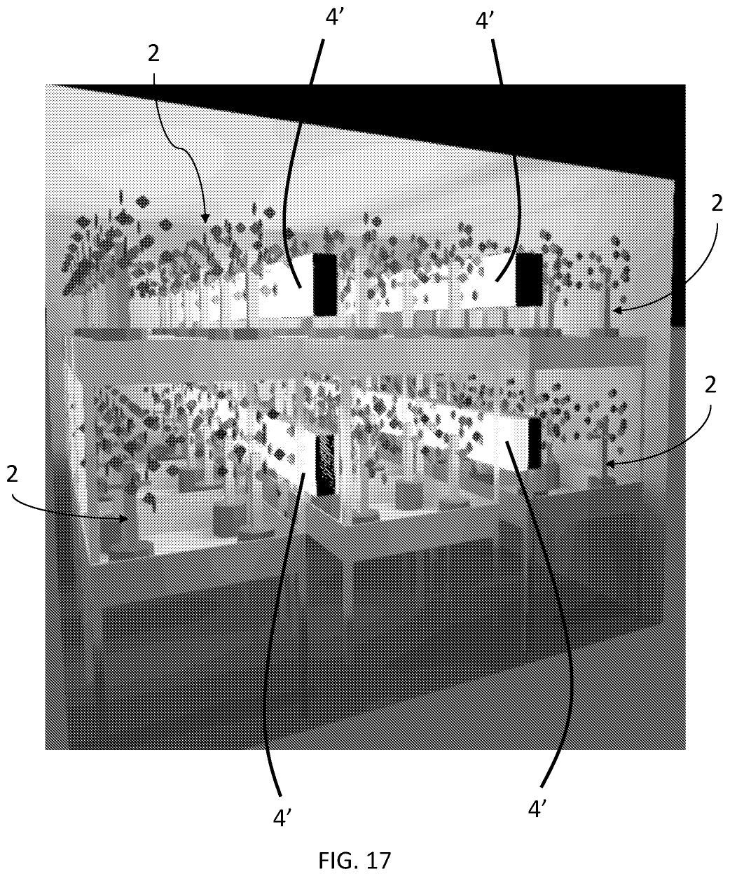

FIG. 17 shows an example lighting arrangement wherein light panels 4′ may be utilized according to certain embodiments. Unlike the arrangement shown in FIG. 1, wherein grow lights 4 are positioned above plants 2, the lighting arrangement of FIG. 17 includes grow lights 4′ situated between the sides of plants 2 or between rows of plants 2. In some such embodiments, grow lights 4′ include one or more of light panels 4′ such that light may be emitted from both sides of grow lights 4′ towards the plants 2 positioned on either side of grow lights 4′. It should be appreciated that, in some embodiments, a combination of overhead grow lights 4 and grow lights 4′ may be used in certain lighting systems in order to provide light to plants 2 from multiple directions.

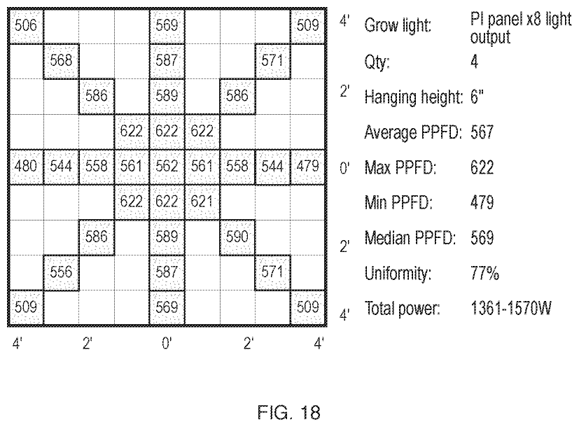

As discussed above, a benefit of using light panels disclosed herein is that more uniform light may be provided to grow areas 6 and plants 2. Uniformity is defined herein as the minimum light intensity divided by the maximum light intensity across a certain illuminated area. Light uniformity distribution is an important factor to consider when choosing a horticultural light. Existing horticultural lights typically give the highest yield in the center of the light field where the light intensity is the highest, while the yield can drop significantly as one moves away from the center. In the case of horticultural lighting, typically a 4′ by 4′ grow area is studied. FIG. 18 shows an example of simulated light intensity map using a light panel according to an embodiment of the present disclosure for a 4′ by 4′ grow area at 6 inches hanging height above the top of the plants. Values are expressed in Photosynthetic Photon Flux Density (PPFD) in units of mol m⁻²s⁻¹. As indicated in FIG. 18, the maximum PPFD value achieved was 662 while the minimum PPFD value achieved was 479, resulting in a 77% uniformity (479 divided by 622). In comparison, most existing light fixtures offer less than 50% uniformity in a 4′ by 4′ grow area at a specific hanging height. Lighting panels according to embodiments of the present disclosure may produce greater than 50%, greater than 60%, greater than 70%, or greater than 80% uniformity.

The grow lights 4, 4′ of the present disclosure, when used in horticultural light systems, may be configured to have a PPFD of at least about 80 μmol/s·m², for example, about 80 μmol/s·m² to about 750 μmol/s·m², e.g., about 100 μmol/s·m², about 150 μmol/s·m², about 200 μmol/s·m², about 250 μmol/s·m², about 300 μmol/s·m², about 350 μmol/s·m², about 400 μmol/s·m²m, about 450 μmol/s·m², about 500 μmol/s·m², about 550 μmol/s·m², about 600 μmol/s·m², about 650 μmol/s·m², about 700 μmol/s·m², about 750 μmol/s·m², PFFD. In comparison, typical general lighting outputs five to times less. In some embodiments, therefore, grow lights 4, 4′ may generate significant amounts of thermal energy which may require specific consideration. For example, lighting systems according to embodiments of the present disclosure may further include thermal management systems for dissipating heat. The thermal management systems may include passive systems, e.g., a thermal sink incorporated into the light panels disclosed herein, and/or active cooling systems, e.g., fans, liquid cooling systems, refrigeration systems, etc. In some embodiments, for example, fixture frame of the light panels disclosed herein may be made of a thermally conductive material configured to conduct heat away from the LEDs. For example, in some embodiments, the fixture frame may include or be constructed from aluminum, copper, or other thermally conductive metals or their alloys. In some embodiments, the fixture frame may include additional structures to help dissipate heat, for example, external fins, grooves, or ridges to increase the surface area or the fixture frame. Such structures may also be incorporated into other aspects of the light panels disclosed herein, for example, on a cover. Heat spreaders, heat pipes, or heat exchangers may also be included. As mentioned, lighting systems according to the present disclosure may alternatively or additionally include active thermal management systems which may use external devices to enhance heat transfer. Such active thermal management systems may be configured to increase the rate of fluid flow during convection for heat removal, for example, blowers or fans configured to move air around the light panels disclosed herein. Other examples of active heat management systems that may be utilized include thermoelectric coolers (TECs), and forced liquid cooling coils which may be positioned in or proximate to the light panels.

It should be understood that various changes, substitutions, and alterations can be made herein without departing from the spirit and scope of the disclosure. It should also be apparent that individual elements identified herein as belonging to a particular embodiment may be included in other embodiments of the disclosure. Moreover, the scope of the present application is not intended to be limited to the particular embodiments of the process, machine, manufacture, and composition of matter, means, methods and steps described in the specification. As one of ordinary skill in the art will readily appreciate from the disclosure herein, processes, machines, manufacture, composition of matter, means, methods, or steps that perform substantially the same function or achieve substantially the same result as the corresponding embodiments described herein may be utilized according to the present disclosure.

We claim:

1. A grow light for providing light to one or more plants in a grow area, comprising:
a light source;
a first energy conversion component disposed over a first portion of the light source and a second energy conversion component disposed over a second portion of the light source;
a power supply configured to provide power to the light source; and
a controller configured to control the power supply to control an intensity of the light source,
the first energy conversion component configured to convert light received from the first portion into a light having a first spectrum and the second energy conversion component configured to convert light received from the second portion into a light having a second spectrum different from the first spectrum.

2. The grow light of claim 1, wherein the first spectrum has a peak intensity in blue wavelength range and the second spectrum has a peak intensity in red or yellow wavelength range.

3. The grow light of claim 1, wherein the controller is configured to supply power to either the first or the second portions of the light source in response to one or more sensed parameters.

4. The grow light of claim 3, wherein the one or more sensed parameters are selected from the group consisting of: time of day, season, plant surface temperature, surrounding air temperature, moisture/humidity level, plant type of the one or more plants, height of the one or more plants, chemical levels in the one or more plants, stage of growth of the one or more plants, carbon dioxide level, oxygen level, and light reflectance off of the one or more plants.

5. The grow light of claim 1, wherein the first portion and the second portion of the light source have different emission characteristics.

6. The grow light of claim 1, wherein the light source comprises blue light emitting diodes.

7. The grow light of claim 1, wherein the first and the second energy conversion components are removably coupled to the grow light.

8. The grow light of claim 1, wherein the first and second portions of the light source are disposed on different edges of a light guide panel such that the first and the second energy conversion components are respectively disposed between the first and second portions and corresponding edges of the light guide panel.

9. A grow light for providing light to one or more plants in a grow area, comprising:
a light source having a front face, the light source configured to emit light through the front face to illuminate the grow area;
an energy conversion component comprising a plurality of portions, the energy conversion component being positioned in one of the plurality of portions to the front face, wherein each of the plurality of portions of the energy conversion component converts light received from the light source into light having a different spectrum; and
a controller configured to position the energy conversion component to cause a respective portion among the plurality of portions of the energy conversion component to be exposed to the front face in response to one or more sensed parameters.

10. A horticultural lighting system for providing light to one or more plants in a grow area comprising:
a grow light including one or more light panels spaced away from the grow area, each of the one or more light panels including:
a frame;
at least one light emitting diode coupled to an interior of an edge of the frame;
a light guide panel positioned in the frame, an edge of the light guide panel in communication with the at least one light emitting diode; and
at least one color conversion sheet coupled to a front surface of the light guide panel,
the grow light configured to output a uniformity of light outputted through the front surface of the light guide panel that is greater than 50%.

11. The horticultural lighting system of claim 10, wherein the lighting system is configured to transition from a first configuration having the one or more light panels being spaced away from the grow area by a first distance, to a second configuration, having the one or more light panels being spaced away from the grow area by a second distance that is different than the first distance.

12. The horticultural lighting system of claim 11, wherein the lighting system is configured to transition from the first configuration to the second configuration in response to one or more sensed parameters.

13. The horticultural lighting system of claim 12, wherein the one or more sensed parameters are selected from the group consisting of: time of day, season, plant surface temperature, surrounding air temperature, moisture/humidity level, plant type of the one or more plants, height of the one or more plants, chemical levels in the one or more plants, stage of growth of the one or more plants, carbon dioxide level, oxygen level, and light reflectance off of the one or more plants.

14. The horticultural lighting system of any one of claims 10-13, wherein the at least one light emitting diode emits blue light.

15. The horticultural lighting system of any one of claims 10-14, wherein the at least one color conversion sheet is removable from the horticultural lighting system and replaceable by a different color conversion sheet.

16. The horticultural lighting system of any one of claims 10-15, further comprising at least a second color conversion sheet coupled to a rear surface of the light guide panel.

17. A method of cultivating one or more plants positioned in a grow area comprising:
obtaining a grow light configured to provide light to the one or more plants, the grow light including one or more light panels spaced away from the grow area, each of the one or more light panels including:
a frame;
at least one light emitting diode coupled to an interior of an edge of the frame;
a light guide panel positioned in the frame, an edge of the light guide panel in communication with the at least one light emitting diode; and
at least one energy conversion film coupled to a front surface of the light guide panel,
outputting, using the grow light, a light through the front surface of the light guide panel having uniformity which is greater than 50%.

18. The method of claim 17, further comprising adjusting the distance that the grow light is spaced away from the grow area in response to one or more sensed parameters.

19. The method of claim 18, wherein the one or more sensed parameters are selected from the group consisting of: time of day, season, plant surface temperature, surrounding air temperature, moisture/humidity level, plant type of the one or more plants, height of the one or more plants, chemical levels in the one or more plants, stage of growth of the one or more plants, carbon dioxide level, oxygen level, and light reflectance off of the one or more plants.

20. The method of any one of claims 17-19, further comprising replacing the at least one energy conversion film with a different energy conversion film.

21. A grow light for providing light to one or more plants in a grow area, comprising:
a frame;
an opaque reflector positioned within the frame;
a light source disposed on the frame; and
a first energy conversion component disposed over a first portion of the light source and a second energy conversion component disposed over a second portion of the light source,
the first energy conversion component configured to convert light received from the first portion into a light having a first spectrum and the second energy conversion component converts light received from the second portion into a light having a second spectrum different from the first spectrum.

22. A grow light control system for providing light to a plant in a grow area, comprising:
a light source configured to emit source light to the plant in the grow area, the source light having a source light characteristic;
a light sensor configured to:
detect reflected light from the plant, the reflected light having a reflection wavelength spectrum, and
generate reflected light sensor data representative of the reflected light having the reflection wavelength spectrum;
a controller configured to:
receive the reflected light sensor data, and
determine any needed modification of the source light characteristic of the source light based on the reflected light sensor data and plant characteristic criteria.

23. The grow light control system of claim 22, wherein the light sensor includes a photodiode.

24. The grow light control system of claim 22, wherein the light sensor detects reflected light from the plant having a wavelength in a range from 660 nm to 760 nm.

25. The grow light control system of claim 22, wherein the source light characteristic includes a source light intensity of the light source.

26. The grow light control system of claim 25, further comprising:
a power source configured to power the light source based on an amount of power transmitted to the light source,
wherein the controller is configured to alter the source light intensity of the light source by altering the amount of power transmitted by the power source to the light source.

27. The grow light control system of claim 22, wherein the source light characteristic includes a light wavelength spectrum of the light source.

28. The grow light control system of claim 27, further comprising:
an energy conversion component disposed between the light source and the plant in the grow area, the energy conversion component configured to alter the light wavelength spectrum of the source light based on a characteristic of the energy conversion component, and
wherein the controller is configured to alter the light wavelength spectrum of the source light by altering the characteristic of the energy conversion component.

29. The grow light control system of claim 27, wherein the plant characteristic criteria includes a criterion met when the plant transitions from a germination stage to a vegetative stage, and wherein the controller is configured to alter the light wavelength spectrum from being predominantly red wavelength range of 625 nm to 700 nm to having an increased amount of blue light in the 440 to 470 nm.

30. The grow light control system of claim 27, wherein the plant characteristic criteria includes a criterion is met when the plant transitions from a vegetative stage to a reproductive stage, and wherein the controller is configured to alter the light wavelength spectrum from having a peak in red wavelength range of 625 nm to 700 nm to having an increased amount of light in the blue wavelength range of 440 nm to 470 nm.

31. The grow light control system of claim 22, wherein the controller is configured to determine any needed modification of the source light characteristic of the source light based on the reflected light sensor data and plant characteristic criteria by the controller being configured to:
determine whether the reflected light sensor data meets plant stage transition criteria;
in response to a determination that the reflected light sensor data meets plant stage transition criteria, modifying the source light characteristic of the source light; and
in response to a determination that the reflected light sensor data does not meet plant stage transition criteria, refrain from modifying the source light characteristic of the source light.

32. A growth control sensor for a grow light system, the sensor comprising:
an excitation light source configured to provide an excitation light pulse to a plant;
a photodetector configured to receive a light emitted from the plant in response to the excitation light received by the plant and generate an electrical signal based on the received light;
a filter circuit configured to process the electrical signal to remove components of the electrical signal generated by ambient light surrounding the plant to generate a data signal,
a communication circuit configured to transmit the data signal to enable data storage for further processing,
wherein the data signal is representative of a fluorescence output from leaves of the plant.

33. The growth control sensor of claim 32, wherein the filter circuit is configured to:
receive a first electrical signal generated by the ambient light prior to the excitation pulse being provided by the excitation light source,
receive a second electrical signal generated by the light in response to the excitation pulse, and
subtract the first electrical signal from the second electrical signal to generate a data signal.

34. The growth control sensor of claim 32, wherein the photodetector is configured to detect fluorescence light from the plant having a wavelength in a range from 660 nm to 760 nm.

35. The growth control sensor of claim 32, wherein the photodetector comprises an optical cutoff filter.

36. The growth control sensor of claim 32, wherein the photodetector comprises a sensor selected from the group consisting of a photodiode, avalanche photodiode, a PIN diode, a charge-coupled device, a CMOS image sensor, a photomultiplier tube (PMT), and a combination thereof.

37. The growth control sensor of claim 32, wherein the excitation light source is configured to emit the excitation pulse at an intensity such that the second electrical signal has a signal-to-noise ratio of greater than 1.5.

38. The growth control sensor of claim 32, wherein the excitation light source is configured to emit the excitation pulse at an intensity in a range from 400 μmol/m²s to 800 μmol/m²s.

39. The growth control sensor of claim 32, wherein the excitation light pulse has a wavelength in a range from 440 nm to 495 nm.

40. A method of detecting the photosynthetic activity of a plant, the method comprising:
generating, by a photodetector, a first electrical signal based on an ambient light detected by the photodetector;
turning on an excitation light source;
generating, by the photodetector, a second electrical signal based a fluorescence light detected by the photodetector; and
subtracting the first electrical signal from the second electrical signal to generate a fluorescence signal representative of a fluorescence output from leaves of the plant.

41. The method of claim 40, wherein the excitation light source is configured to emit an excitation pulse at an intensity in a range from 400 μmol/m²s to 800 μmol/m²s.

42. The method of claim 40, wherein the photodetector is configured to detect the fluorescence light from the plant having a wavelength in a range from 660 nm to 760 nm.

43. The method of claim 40, wherein the fluorescence signal has a signal to noise ratio of greater than 1.5.

44. A horticultural lighting system, comprising:
the growth control sensor of claim 32; and
a dimmable grow light configured to emit light to a plant in a grow area.

45. The horticulture lighting system of claim 44, further comprising an energy conversion component disposed between the dimmable grow light and the plant in the grow area, the energy conversion component configured to alter the light wavelength spectrum of a light emitted by the dimmable grow light based on a characteristic of the energy conversion component, and
a controller coupled to the growth control signal and configured to cause a change in light wavelength spectrum of the light emitted by the dimmable grow light by altering the characteristic of the energy conversion component.

46. A horticultural lighting system comprising:
the growth control sensor of claim 32;
a grow light configured to emit light to a plant in a grow area; and
a control system configured to control one or more of temperature of air surrounding the plant, moisture/humidity level of an environment surrounding the plant, chemical levels in the plant, carbon dioxide level surrounding the plant, oxygen level surround the plant, and light intensity of the light emitted by the grow light.

47. A growth control sensor, comprising:
an excitation light source configured to provide light having a wavelength in a range from 400 nm to 500 nm to a plant; and
a photodetector configured to measure a light reflected and emitted from the plant in response to receiving a light from the excitation light source,
wherein the excitation light source has an intensity in a range from 400 μmol/m²s to 8000 μmol/m²s,
wherein the measured light reflected and emitted from the plant is indicative of a measure of photosynthesis rate of the plant.

48. A method of remotely measuring plant photosynthesis rate, the method comprising:
providing an excitation light having a wavelength in a range from 400 nm to 500 nm to the plant at an intensity in a range from 400 μmol/m²s to 8000 μmol/m²s; and
measuring a light reflected and emitted from the plant in response to the excitation light, wherein the measured light is indicative of the plant photosynthesis rate.

49. A grow light for providing light to one or more plants in a grow area, comprising:
a frame;
a light source disposed along an interior of an edge of the frame;
a light guide panel disposed in the frame, an edge of the light guide panel being in communication with the light source disposed on the interior of the corresponding edge of the frame, the light guide panel being configured to direct light received from the light source through a first surface of the light guide panel to a viewing hemisphere; and
a first energy conversion component disposed over a first portion of the light source and a second energy conversion component disposed over a second portion of the light source,
the first energy conversion component configured to convert light received from the first portion into a light having a first spectrum and the second energy conversion component configured to convert light received from the second portion into a light having a second spectrum different from the first spectrum.
